(19) United States
(12) Patent Application Publication
(10) Pub. No.: US 2022/0223604 A1
(43) Pub. Date: Jul. 14, 2022

(54) SEMICONDUCTOR STRUCTURE HAVING COMPOSITE MOLD LAYER

(71) Applicant: Samsung Electronics Co., Ltd., Suwon-si (KR)

(72) Inventors: Hwanyeol PARK, Seoul (KR); Hwanwoo KIM, Seoul (KR); Jongkyu LEE, Hwaseong-si (KR); Chulhwan CHOI, Seoul (KR)

(73) Assignee: Samsung Electronics Co., Ltd., Suwon-si (KR)

(21) Appl. No.: 17/469,349

(22) Filed: Sep. 8, 2021

(30) Foreign Application Priority Data
Jan. 11, 2021 (KR) 10-2021-0003566

(51) Int. Cl. H01L 27/108; H01L 25/065

(52) U.S. Cl. CPC H01L 27/10897; H01L 27/10805; H01L 25/0655

(57) ABSTRACT

A semiconductor structure of the inventive concepts includes a chip region comprising a plurality of semiconductor chips on the substrate; and a peripheral region at a periphery of the chip region, the peripheral region including a mold structure. The mold structure may include a base mold layer on the substrate, and a composite mold layer on the base mold layer, the composite mold layer comprising at least one bowing sacrificial layer and at least one bowing prevention layer.

### CROSS-REFERENCE TO RELATED APPLICATION

This application is based on and claims priority under 35 U.S.C. § 119 to Korean Patent Application No. 10-2021-0003566, filed on Jan. 11, 2021, in the Korean Intellectual Property Office, the disclosure of which is incorporated by reference herein in its entirety.

### BACKGROUND

The inventive concepts relate to a semiconductor structure, and more particularly, to a semiconductor structure including a mold layer.

Based on the demands for higher integration of semiconductor devices (e.g., dynamic random access memory (DRAM) devices), the size of capacitor of the semiconductor devices is also being reduced. However, even when the size of capacitor decreases, a capacitance required for a unit cell of a semiconductor device has a same value or greater value. Accordingly, a height of the capacitor (e.g., a height of a bottom electrode) increases, and a height of a mold layer for forming the bottom electrode also increases.

### SUMMARY

The inventive concepts provide a semiconductor structure including a mold layer for easily forming a capacitor even despite an increase in a height of the capacitor, that is, a semiconductor structure including a composite mold layer.

According to an embodiment of the inventive concepts, there is provided a semiconductor structure on a substrate, the semiconductor structure including a chip region comprising a plurality of semiconductor chips on the substrate; and a peripheral region at a periphery of the chip region, the peripheral region including a mold structure. The mold structure may include a base mold layer on the substrate, and a composite mold layer on the base mold layer, the composite mold layer comprising at least one bowing sacrificial layer and at least one bowing prevention layer.

According to an embodiment of the inventive concepts, there is provided a semiconductor structure on a substrate, the semiconductor structure including a chip region comprising a plurality of semiconductor chips on the substrate; and a peripheral region at a periphery of the chip region, the peripheral region including a mold structure. The mold structure may include a base mold layer on the substrate, a composite mold layer on the base mold layer, the composite mold layer comprising at least one bowing sacrificial layer and at least one bowing prevention layer; and a supporter layer under the base mold layer or on the composite mold layer.

According to an embodiment of the inventive concepts, there is provided a semiconductor structure on a substrate, the semiconductor structure including a chip region comprising a plurality of semiconductor chips on the substrate; and a peripheral region at a periphery of the chip region and comprising a mold structure. The mold structure may include a lower base mold layer on the substrate, a lower supporter layer on the lower base mold layer, an upper base mold layer on the lower supporter layer, a composite mold layer on the upper base mold layer and comprising at least one bowing sacrificial layer and at least one bowing prevention layer, and an upper supporter layer on the composite mold layer.

### BRIEF DESCRIPTION OF THE DRAWINGS

Example embodiments of the inventive concepts will be more clearly understood from the following detailed description taken in conjunction with the accompanying drawings in which:

FIG. 1 is a top-plan view of a semiconductor structure according to some example embodiments;

FIG. 2 is a cross-sectional view of the semiconductor structure taken along line II-II′ shown in FIG. 1;

FIG. 3 is an enlarged view of a portion of the semiconductor structure shown in FIG. 2, according to some example embodiments;

FIG. 4 is an enlarged view of a portion of the semiconductor structure shown in FIG. 2, according to some example embodiments;

FIG. 5 is an enlarged view of a portion of the semiconductor structure shown in FIG. 2, according to some example embodiments;

FIGS. 6A and 6B are respectively cross-sectional views of a mold structure according to some example embodiments and a mold structure according to a comparison example;

FIG. 7 is a top-plan view of a semiconductor chip included in a semiconductor structure according to some example embodiments;

FIG. 8 is a cross-sectional view taken along line B-B′ shown in FIG. 7;

FIG. 9 is a cross-sectional view of a semiconductor chip included in a semiconductor structure according to some example embodiments;

FIG. 10 is a cross-sectional view of a semiconductor chip included in a semiconductor structure according to some example embodiments;

FIG. 11 is a cross-sectional view of a semiconductor chip included in a semiconductor structure according to some example embodiments;

FIGS. 12 through 18 are cross-sectional views for describing a method of manufacturing a semiconductor chip included in a semiconductor structure according to some example embodiments;

FIGS. 19 and 20 are cross-sectional views for describing a method of manufacturing a semiconductor chip included in a semiconductor structure according to some example embodiments;

FIG. 21 is a top-plan view of a semiconductor chip included in a semiconductor structure according to some example embodiment;

FIG. 22 is a perspective view of the semiconductor chip shown in FIG. 21;

FIGS. 23A and 23B are cross-sectional views respectively taken along lines X1-X1′ and Y1-Y1′ shown in FIG. 21;

FIG. 24 is a top-plan view of a semiconductor chip included in a semiconductor structure according to some example embodiments, and FIG. 25 is a perspective view of the semiconductor chip shown in FIG. 24; and

FIG. 26 illustrates a system including a semiconductor chip that is included in a semiconductor structure according to some example embodiments.

### DETAILED DESCRIPTION OF THE EMBODIMENTS

Hereinafter, example embodiments of the inventive concepts will be described in detail with reference to the accompanying drawings. The following embodiments of the inventive concepts may be implemented by an (e.g., one) example embodiment and/or may also be implemented by combination of one or more embodiments. Therefore, the inventive concepts are not construed as being limited to one embodiment.

Although the terms “first,” “second,” “third,” etc., may be used herein to describe various elements, components, regions, layers, and/or sections, these elements, components, regions, layers, and/or sections, should not be limited by these terms. These terms are only used to distinguish one element, component, region, layer, or section, from another region, layer, or section. Thus, a first element, component, region, layer, or section, discussed below may be termed a second element, component, region, layer, or section, without departing from the scope of this disclosure.

Spatially relative terms, such as “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. The device may be otherwise oriented (rotated 90 degrees or at other orientations) and the spatially relative descriptors used herein interpreted accordingly. In addition, when an element is referred to as being “between” two elements, the element may be the only element between the two elements, or one or more other intervening elements may be present.

When the terms “about” or “substantially” are used in this specification in connection with a numerical value, it is intended that the associated numerical value includes a manufacturing tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

In the present specification, unless other cases are obviously pointed out, singular forms of components may include plural forms of the components. For more clear description of the inventive concepts, elements in the drawings may be exaggerated.

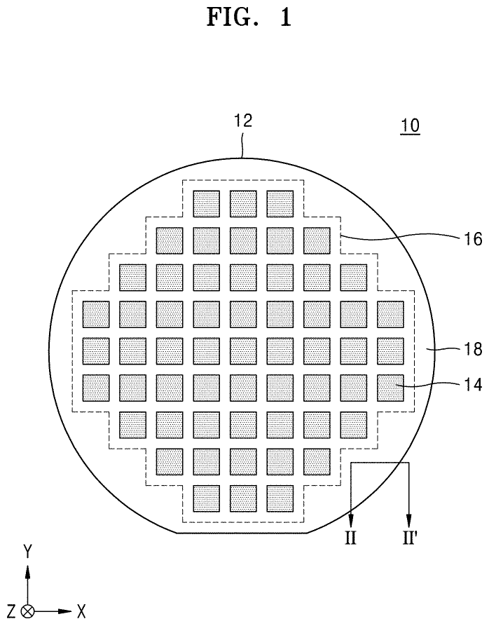

FIG. 1 is a top-plan view of a semiconductor structure according to some example embodiments.

Referring to FIG. 1, a semiconductor substrate 10 may include a chip region 16, which includes a plurality of semiconductor chips (and/or semiconductor devices) 14 on a surface of a substrate 12, and a peripheral region 18 around the chip region 16. The substrate 12 may be and/or include a semiconductor substrate or a semiconductor wafer. For example, the substrate 12 may include a silicon substrate or a silicon wafer.

The semiconductor chips 14 may be formed in the chip region 16 of the substrate 12. For example, except for a portion of an edge of the substrate 12, the chip region 16 may be on (and/or cover) an entire surface of the substrate 12. The semiconductor chips 14 may be dynamic random access memory (DRAM) devices; and each of the semiconductor chips 14 may include a capacitor formed on the substrate 12.

The capacitor may include a bottom electrode, a dielectric layer on the bottom electrode, and a top electrode on the dielectric layer. In some embodiments, a supporter layer may be formed between the bottom electrodes included in the capacitors.

The semiconductor chips 14 may include integrated circuits. An integrated circuit may include a memory circuit and/or a logic circuit. The semiconductor chips 14 may include a plurality of various kinds of individual devices. For example, an individual device may include a metal-oxide-semiconductor (MOS) transistor. The semiconductor chips 14 formed in the chip region 16 will be described later in further detail.

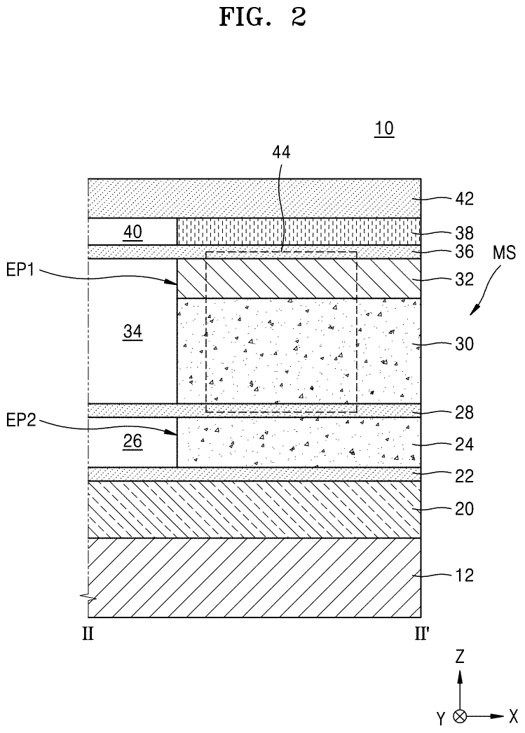

Mold structures may be in the chip region 16 and the peripheral region 18. For example, a mold structure in the peripheral region 18 may include a structure that is made when the semiconductor chips 14 are manufactured. The mold structure may include a structure for forming the capacitors included in the semiconductor chips 14. The mold structure formed in the peripheral region 18 will be described in detail with reference to FIG. 2. In addition, the mold structure formed in the chip region 16 may include an etch stop layer and a supporter layer among components shown in FIG. 2.

FIG. 2 is a cross-sectional view of the semiconductor structure taken along line II-II′ shown in FIG. 1.

FIG. 2 may be a cross-sectional view of the semiconductor structure 10 at a side of the peripheral region 18 (see FIG. 1). The semiconductor structure 10 may include an interlayer insulating layer 20 formed on the substrate 12. The interlayer insulating layer 20 may include an insulator such as silicon dioxide (SiO₂). In some example embodiments, the SiO₂ may be and/or include borophosphosilicate glass (BPSG), tetraethyl orthosilicate (TEOS), and/or phosphosilicate glass (PSG).

The semiconductor structure 10 may include a mold structure MS formed on the interlayer insulating layer 20. The mold structure MS may include an etch stop layer 22, a lower base mold layer 24, a lower supporter layer 28, an upper base mold layer 30, a composite mold layer 32, an intermediate supporter layer 36, a composite mold protection layer 38, and an upper supporter layer 42. The etch stop layer 22 may include an etch selective material compared to another material included in the semiconductor structure 10. For example, in the case where the semiconductor structure includes SiO₂, the etch stop layer 22 may include silicon nitride (SiN). In some embodiments, among the components shown in FIG. 2, only any one of the etch stop layer 22, the lower supporter layer 28, the intermediate supporter layer 36, and the upper supporter layer 42 may remain in the mold structure MS that is formed in the chip region 16 (see FIG. 1).

In some embodiments, the lower base mold layer 24 and the upper base mold layer 30 may include SiO₂. In some embodiments, the lower supporter layer 28, the intermediate supporter layer 36, and/or the upper supporter layer 42 may include the etch selective material with a dopant. For example, in the case wherein the etch stop layer 22 includes SiN, the lower supporter layer 28, the intermediate support layer, and/or the upper support layer 42 may include silicon carbonitride (SiCN). The composite mold layer 32 may include a bowing sacrificial layer and a bowing prevention layer. The composite mold layer 32 will be described later in further detail. The composite mold protection layer 38 may include the etch selective material (e.g., SiN).

A first opening 26, exposing a surface of the etch stop layer 22, may be formed at one side of the lower base mold layer 24. As will be described below, a bowing portion (e.g., a portion of the lower base mold layer 24 having a bow shape) may be not formed on a sidewall EP2 of the first opening 26. A second opening 34 may be formed on one side of the upper base mold layer 30 and one side of the composite mold layer 32. A third opening 40 may be formed at one side of the composite mold protection layer 38.

The semiconductor structure 10 in FIG. 2 includes all of the lower supporter layer 28, the intermediate supporter layer 36, and the upper supporter layer 42. However, the examples embodiments are not limited thereto. For example, in some embodiments, the semiconductor structure 10 may only include at least one of the lower supporter layer 28, the intermediate supporter layer 36, and/or the upper supporter layer 42. In some embodiments, the semiconductor structure 10 may include none of the lower supporter layer 28, the intermediate supporter layer 36, and the upper supporter layer 42. In some embodiments, a thickness of the upper supporter layer 42 may be greater than a thickness of the lower supporter layer 28.

The semiconductor structure 10 in FIG. 2 includes all of the first opening 26, the second opening 34, and the third opening 40, which are separated, respectively, by the lower supporter layer 28 and the intermediate supporter layer 36. However, in some embodiments, when the semiconductor structure 10 does not include the lower supporter layer 28 and/or the intermediate supporter layer 36, the first opening 26, the second opening 34, and/or the third opening 40 may be collectively referred to as an opening.

The semiconductor structure 10 in FIG. 2 includes both of the lower base mold layer 24 and the upper base mold layer 30, which are separated by the lower supporter layer 28. However, in some embodiments, when the semiconductor structure 10 does not include the lower supporter layer 28, the lower base mold layer 24 and the upper base mold layer 30 may be collectively referred to as a base mold layer.

The semiconductor structure 10 may include the composite mold layer 32. The composite mold layer 32 may be in an upper portion of the mold structure MS. When the first opening 26, the second opening 34, and the third opening 40 are formed, the composite mold layer 32 may, as described below, prohibit and/or mitigating an etching concentration of the semiconductor structure 10 due to an uneven concentration of an etching gas (for example, fluorocarbon gas (CₓF_{y})) in the first opening 26, the second opening 34, and/or the third opening 40.

For example, when the first opening 26, the second opening 34, and the third opening 40 are formed, the composite mold layer 32 may prohibit the etching concentration. Accordingly, in the composite mold layer 32, a bowing portion having a bow shape may be not formed on a sidewall EP1 of the second opening 34.

Although the semiconductor structure 10 in FIG. 2 includes the composite mold protection layer 38 formed on the intermediate supporter layer 36, in some embodiments, the composite mold protection layer 38 may be not formed.

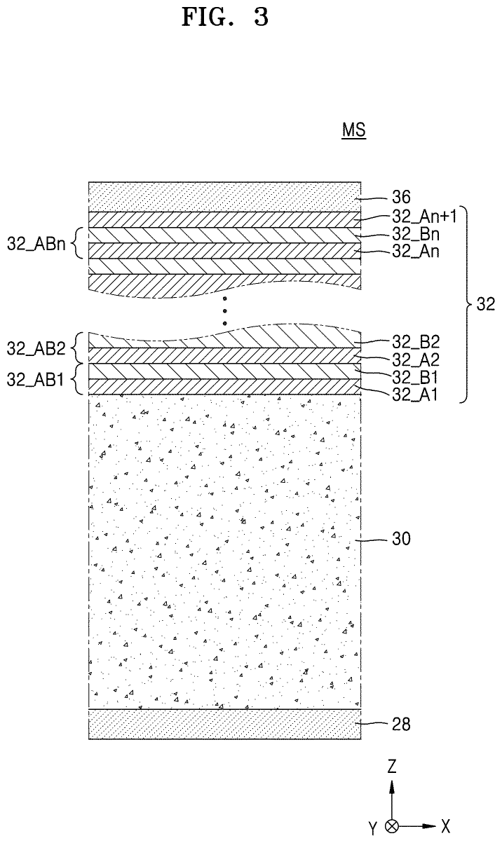

FIG. 3 is an enlarged view of a portion of the semiconductor structure shown in FIG. 2, according to some embodiments.

FIG. 3 is an enlarged view of a portion 44 of the semiconductor structure 10 (see FIG. 2). FIG. 3 is provided to describe a portion of the mold structure MS (see FIG. 2). FIG. 3 is also provided to describe the composite mold layer 32 included in the semiconductor structure 10 (see FIG. 2). The composite mold layer 32 may be on the upper base mold layer 30 that is on the lower supporter layer 28. The composite mold layer 32 may be under the intermediate supporter layer 36.

The composite mold layer 32 may include a material layer, which is provided to prohibit and/or mitigate the etch concentration from forming and/or to prevent (and/or mitigate) the formation of the bowing portion having the bow shape on the sidewall EP1 of the second opening 34 (see FIG. 2) as described above. The composite mold layer 32 may include first through n+1^{th} bowing sacrificial layers 32_A1, 32_A2 through 32_An, and 32_An+1 (where n is a positive integer), and first through n^{th} bowing prevention layers 32_B1, and 32_B2 through 32_Bn (where n is a positive integer).

For example, the composite mold layer 32 may include a plurality of material layers, in which the first through n+1^{th} bowing sacrificial layers 32_A1, 32_A2 through 32_An, and 32_An+1 and the first through n^{th} bowing prevention layers 32_B1 and 32_B2 through 32_Bn are alternately stacked. The composite mold layer 32 may be formed by a deposition method such as chemical vapor deposition (CVD), for example, plasma enhanced CVD (PECVD). In some embodiments, the first through n+1^{th} bowing sacrificial layers 32_A1, 32_A2 through 32_An, and 32_An+1 and the first through n^{th} bowing prevention layers 32_B1 and 32_B2 through 32_Bn, which are included in the composite mold layer 32, may be formed in the same deposition device and/or through an in-situ method.

The upper base mold layer 30 may have a greater thickness than those of the first through n+1^{th} bowing sacrificial layers 32_A1, 32_A2 through 32_An, and 32_An+1 (and/or than the composite mold layer 32). The upper base mold layer 30 may include a same material as the first through n+1^{th} bowing sacrificial layers 32_A1, 32_A2 through 32_An, and 32_An+1, and/or may include a different material from the first through n^{th} bowing prevention layers 32_B1 and 32_B2 through 32_Bn.

The composite mold layer 32 may include a first bowing prevention composite layer 32_AB1, which includes the first bowing sacrificial layer 32_A1 and the first bowing prevention layer 32_B1 on the upper base mold layer 30, and a second bowing prevention composite layer 32_AB2, which includes the second bowing sacrificial layer 32_A2 and the second bowing prevention layer 32_B2 on the first bowing prevention composite layer 32_AB1.

A plurality of first bowing prevention composite layers 32_AB1 and a plurality of second bowing prevention composite layers 32_AB2 may be sequentially stacked on the upper base mold layer 30. For example, the composition mold layer 32 may include a bowing prevention composite layer 32_ABn (where n is a positive integer). In some embodiments, in the composite mold layer 32, the additional bowing sacrificial layer 32_An+1 may be further formed on a final structure in which the plurality of bowing prevention composite layers 32_AB1 through 32_ABn are sequentially stacked (e.g., the additional bowing sacrificial layer 32_An+1 may be formed on an upper most bowing prevention composite layer 32_ABn).

Each of the material layers included in the first through n+1^{th} bowing sacrificial layers 32_A1, 32_A2 through 32_An, and 32_An+1 may be formed in a thickness of several mms so as to prevent changes in a profile (e.g., an etch profile) on the sidewall EP1 (see FIG. 2) of the mold structure MS (see FIG. 2). For example, each of the material layers included in the first through n+1^{th} bowing sacrificial layers 32_A1, 32_A2 through 32_An, and 32_An+1 may be formed to a thickness of 10 mm or less, for example, to a thickness from about 1 nm to about 10 nm.

Each of the material layers included in the first through n^{th} bowing prevention layers 32_B1, 32_B2 through 32_Bn may be formed in a thickness of several nm to prevent changes in the profile (e.g., the etch profile) of the sidewall EP1 (see FIG. 2) of the mold structure MS (see FIG. 2). For example, each of the material layers included in the first through n^{th} bowing prevention layers 32_B1 and 32_B2 through 32_Bn may be formed to a thickness of 10 nm or less, for example, to a thickness from about 1 nm to about 10 nm.

The first through n+1^{th} bowing sacrificial layers 32_A1, 32_A2 through 32_An, and 32_An+1 may include a material that is easily etched by an etch gas (e.g., a CₓF_{y}-based gas) selected for etching a material (e.g., SiO₂) included in the upper base mold layer 30 and/or the lower base mold layer 24 (see FIG. 2).

For example, in some embodiments, where the etch gas is selected to etch SiO₂, the first through n+1^{th} bowing sacrificial layers 32_A1, 32_A2 through 32_An, and 32_An+1 may include SiO₂, silicon oxynitride (SiON), and/or SiO₂ doped with a non-metal element. In some embodiments, the SiO₂ doped with a non-metal element may include SiO₂ doped with at least one of hydrogen (H), carbon (C), boron (B), and/or arsenic (As).

The first through n^{th} bowing prevention layers 32_B1 and 32_B2 through 32_Bn may include a material that is not easily etched by the etch gas (e.g., a CₓF_{y}-based gas) for etching (e.g., SiO₂ included in) the upper base mold layer 30 and/or the lower base mold layer 24 (see FIG. 2). For example, the material included in the first through n^{th} bowing prevention layers 32_B1 and 32_B2 through 32_Bn may be considered an etch selective and/or an etch resistant material with regards to the etch gas.

In some embodiments, the first through n^{th} bowing prevention layers 32_B1, 32_B2 through 32_Bn may include silicon nitride (SiN) and/or SiN doped with a non-metal element. SiN doped with a non-metal element may include SiN doped with at least one of H, C, B, and/or As.

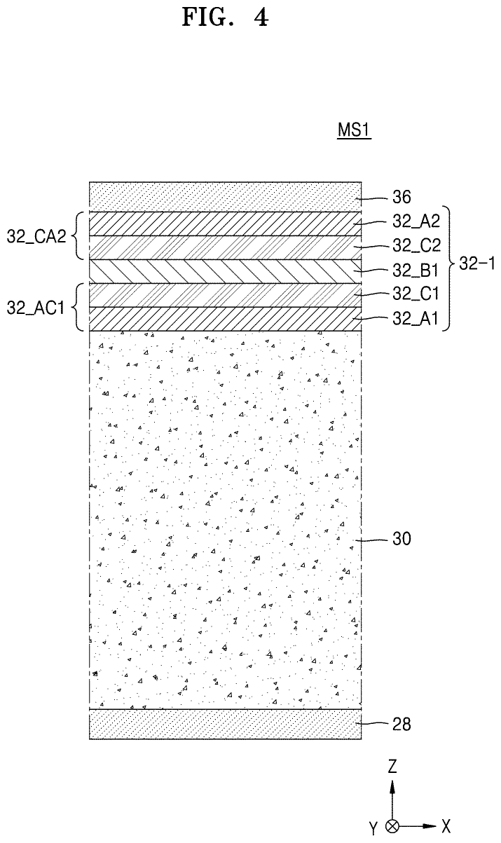

FIG. 4 is an enlarged view of a portion of the semiconductor structure shown in FIG. 2, according to some example embodiments.

FIG. 4 is an enlarged view of a portion 44 of the semiconductor structure 10 (see FIG. 2). Compared to the mold structure MS in FIG. 3, a mold structure MS1 in FIG. 4 may be identical to the mold structure MS in FIG. 3, except that the mold structure MS1 includes a composite mold layer 32-1. In FIG. 4, descriptions that are the same as those of FIG. 3 will be briefly described or omitted.

The composite mold layer 32-1 may include a material layer, which, as described above, is provided to prohibit and/or mitigate the etch concentration and/or to prevent the formation of the bowing portion having the bow shape on the sidewall EP1 of the second opening 34 (see FIG. 2). The composite mold layer 32-1 may include the first bowing sacrificial layer 32_A1, the second bowing sacrificial layer 32_A2, the first bowing prevention layer 32_B1, a first bowing prevention buffer layer 32_C1, and a second bowing prevention buffer layer 32_C2. In some embodiments, the composite mold layer 32-1 may have a thickness that is less than that of the composite mold layer 32 in FIG. 3.

The composite mold layer 32-1 may be formed by a deposition method (e.g., CVD, for example, PECVD). The first bowing sacrificial layer 32_A1, the second bowing sacrificial layer 32_A2, the first bowing prevention layer 32_B1, the first bowing prevention buffer layer 32_C1, and the second bowing prevention buffer layer 32_C2, which are included in the composite mold layer 321, may be formed using the same deposition device and/or through an in-situ method.

The first bowing prevention buffer layer 32_C1 and the second bowing prevention buffer layer 32_C2 may be among (e.g., between) the first bowing sacrificial layer 32_A1, the second bowing sacrificial layer 32_A2, and the first bowing prevention layer 32_B1. The upper base mold layer 30 may have a thickness greater than that of the first bowing sacrificial layer 32_A1 and/or the second bowing sacrificial layer 32_A2. The upper base mold layer 30 may include a material that is the same as the first bowing sacrificial layer 32_A1 and the second bowing sacrificial layer 32_A2, and may include a material that is different from those of the first bowing prevention layer 32_B1, the first prevention buffer layer 32_C1, and the second prevention buffer layer 32_C2.

The composite mold layer 32-1 may include a first bowing prevention composite layer 32_AC1, which includes the first bowing sacrificial layer 32_A1 and the first bowing prevention buffer layer 32_C1 that are sequentially formed on the upper base mold layer 30. For example, the composite mold layer 32-1 may include the first bowing prevention layer 32_B1 formed on the first bowing prevention composite layer 32_AC1. The composite mold layer 32-1 may include a second bowing prevention composite layer 32_CA2, which includes the second bowing prevention buffer layer 32_C2 and the second bowing sacrificial layer 32_A2 that are sequentially formed on the first bowing prevention layer 32_B1.

Each of material layers included in the first bowing sacrificial layer 32_A1, the second bowing sacrificial layer 32_A2, the first bowing prevention layer 32_B1, the first bowing prevention buffer layer 32_C1, and the second bowing prevention buffer layer 32_C2 may be formed to a thickness of several nm. For example, each of the material layers included in the first bowing sacrificial layer 32_A1, the second bowing sacrificial layer 32_A2, the first bowing prevention layer 32_B1, the first bowing prevention buffer layer 32_C1, and/or the second bowing prevention buffer layer 32_A2 may be formed to a thickness of 10 nm and/or less (for example, to a thickness from about 1 nm to about 10 nm).

The first bowing sacrificial layer 32_A1 and the second bowing sacrificial layer 32_A2 may each include a material that is easily etched by an etch gas (e.g., a CₓF_{y}-based gas) for etching a material (e.g., SiO₂) included in the upper base mold layer 30 and/or the lower base mold layer 24 (see FIG. 2).

For example, in some embodiments, wherein the etch gas is selected to etch SiO₂, the first bowing sacrificial layer 32_A1 and the second bowing sacrificial layer 32_A2 may each include SiO₂, SiON, and/or SiO₂ doped with a non-metal element. The non-metal element may include at least one of H, C, B, and/or As.

The first bowing prevention layer 32_B1 may include a material that is not easily etched by the etch gas (e.g., a CₓF_{y}-based gas) for etching the material (e.g., SiO₂) included in the upper base mold layer 30 and/or the lower base mold layer 24 (see FIG. 2). For example, the material included in the first bowing prevention layer 32_B1 may be considered an etch selective and/or an etch resistant material with regards to the etch gas.

In some embodiments, the first bowing prevention layer 32_B1 may include SiN and/or SiN doped with a non-metal element. SiN doped with the non-metal element may include SiN doped with at least one of H, C, B, and/or As.

The first bowing prevention buffer layer 32_C1 and the second bowing prevention buffer 32_C2 may include a material that is easily etched by the etch gas (e.g., a CₓF_{y}-based gas) for etching SiO₂ included in the upper base mold layer 30 or the lower base mold layer 24 (see FIG. 2). In some embodiments, in the presence of the etch gas, the first bowing prevention buffer layer 32_C1 and the second bowing prevention buffer 32_C2 may etch at a different rate than the first bowing sacrificial layer 32_A1 and the second bowing sacrificial layer 32_A2.

In some embodiments, the first bowing prevention buffer layer 32_C1 and the second bowing prevention buffer layer 32_C2 may include SiON and/or SiON doped with a non-metal element. SiON doped with the non-metal element may include SiON doped with at least one of H, C, B, and/or As.

In some embodiments, when the first bowing prevention buffer layer 32_C1 and the second bowing prevention buffer layer 32_C2 include SiO₁₋ₓNₓ (where 0<X<1), the first bowing sacrificial layer 32_A1 and the second bowing sacrificial layer 32_A2 may include SiO₁₋ₓ (where X=0, e.g., SiO₁₋ₓNₓ may be SiO), and the first bowing prevention layer 32_B1 may include SiO₁₋ₓNₓ (where X=1, e.g., SiO₁₋ₓNₓ may be SiN).

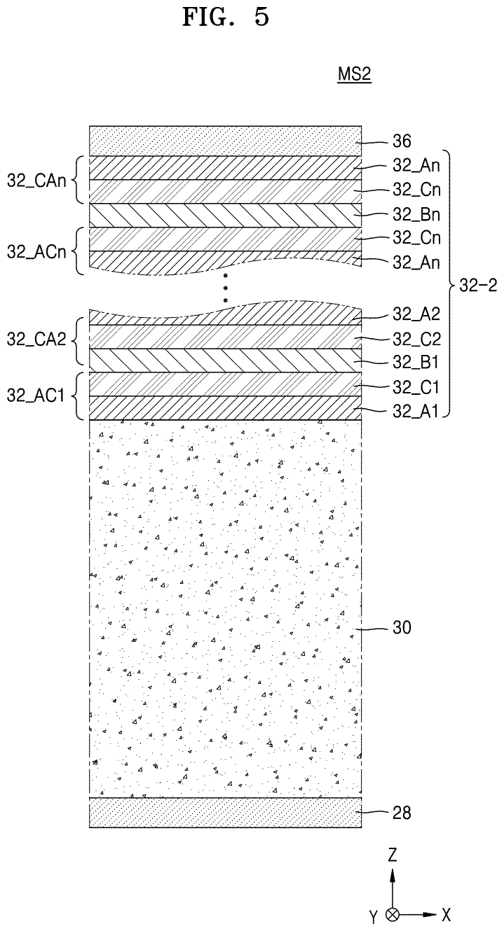

FIG. 5 is an enlarged view of a portion of the semiconductor structure shown in FIG. 2, according to some example embodiments.

FIG. 5 is an enlarged view of the portion 44 of the semiconductor structure 10 (see FIG. 2). Compared to the mold structures MS and MS1 respectively shown in FIGS. 3 and 4, a mold structure MS2 in FIG. 5 may be identical to the mold structures MS and MS1, except that the mold structure MS2 includes a composite mold layer 32-2. In FIG. 5, descriptions that are the same as those of FIGS. 3 and/or 4 will be briefly described or omitted.

The composite mold layer 32-2 may include the first through n^{th} bowing sacrificial layers 32_A1, 32_A2 through 32_An (where n is a positive integer), the first through n^{th} bowing prevention layers 32_B1 through 32_Bn, and first through n^{th} bowing prevention buffer layers 32_C1, 32_C2 through 32_Cn. In some example embodiments, a thickness of the composite mold layer 32-2 may be greater than that of the composite mold layer 32-1 in FIG. 4.

The composite mold layer 32-2 may be formed by a deposition method such as CVD (for example, by PECVD). The first through n^{th} bowing sacrificial layers 32_A1 and 32_A2 through 32_An, the first through n^{th} bowing prevention layers 32_B1 through Bn, and the first through n^{th} bowing prevention buffer layers 32_C1 and 32_Cn through 32_Cn, which are included in the composite mold layer 32-2, may be formed in the same deposition device, and/or through an in-situ method.

The first through n^{th} bowing prevention buffer layers 32_C1 and 32_C2 through 32_Cn may be among (e.g., between) the first through n^{th} bowing sacrificial layers 32_A1 and 32_A2 through 32_An and the first through n^{th} bowing prevention layers 32_B1 through 32_Bn. The upper base mold layer 30 may include a material that is the same as the first through n^{th} bowing sacrificial layers 32_A1 and 32_A2 through 32_An, and may include a material that is different from those of the first through n^{th} bowing prevention layers 32_B1 through 32_Bn and the bowing prevention buffer layers 32_C1 and 32_C2 through 32_Cn.

The composite mold layer 32-2 may include the first bowing prevention composite layer 32_AC1, which includes the first bowing sacrificial layer 32_A1 and the first bowing prevention buffer layer 32_C1 that are sequentially formed on the upper base mold layer 30.

The composition mold layer 32-2 may include the first bowing prevention layer 32_B1 formed on the first bowing prevention composite layer 32_AC1. The composite mold layer 32-2 may include the second bowing prevention composite layer 32_C2, which includes the second bowing prevention buffer layer 32_C2 and the second bowing sacrificial layer 32_A2 that are sequentially formed on the first bowing prevention layer 32_B1.

The first bowing prevention composite layer 32_AC1 and the second bowing prevention composite layer 32_CA2 may be sequentially stacked on the upper base mold layer 30. By doing so, the composite mold layer 32-2 may include bowing prevention composite layers 32_ACn and 32_CAn (where n is a positive integer).

Each of material layers included in the first through n^{th} bowing sacrificial layers 32_A1 and 32_A2 through 32_An, the first through n^{th} bowing prevention layers 32_B1 through 32_Bn, and the first through n^{th} bowing prevention buffer layers 32_C1 and 32_C2 through 32_Cn may be formed in to thickness of several nm. For example, each of the material layers included in the first through n^{th} bowing sacrificial layers 32_A1 and 32_A2 through 32_An, the first through n^{th} bowing prevention layers 32_B1 through 32_Bn, and/or the first through n^{th} bowing prevention buffer layers 32_C1 and 32_C2 through 32_Cn may be formed to a thickness of 10 nm or less (for example, to a thickness from about 1 nm to about 10 nm).

The first through n^{th} bowing sacrificial layers 32_A1 and 32_A2 through 32_An may include a material that is easily etched by an etch gas (e.g., a CₓF_{y}-based gas) for etching a material (e.g., SiO₂) included in the upper base mold layer 30 and/or the lower base mold layer 24 (see FIG. 2).

For example, in some embodiments, wherein the etch gas is selected to etch SiO₂, the first through n^{th} bowing sacrificial layers 32_A1 and 32_A2 through 32_An may include SiO₂, SiON, and/or SiO₂ doped with a non-metal element. SiO₂ doped with the non-metal element may include SiO₂ doped with at least one of H, C, B, and/or As.

The first through n^{th} bowing prevention layers 32_B1 through 32_Bn may include a material that is not easily etched by the etch gas (e.g., a CₓF_{y}-based gas) for etching the material (e.g., SiO₂) included in the upper base mold layer 30 or the lower base mold layer 24 (see FIG. 2).

In some embodiments, the first through n^{th} bowing prevention layers 32_B1 through 32_Bn may include SiN and/or SiN doped with a non-metal element. SiN doped with the non-metal element may include SiN doped with at least one of H, C, B, and/or As.

The first through n^{th} bowing prevention buffer layers 32_C1 and 32_C2 through 32_Cn may include a material that is easily etched by an etch gas (e.g., a CₓF_{y}-based gas) for etching the material (e.g., SiO₂) included in the upper base mold layer 30 or the lower base mold layer 24 (see FIG. 2).

In some embodiments, the first through n^{th} bowing prevention buffer layers 32_C1, 32_C2 through 32_Cn may include SiON or SiON doped with a non-metal element. SiON doped with the non-metal element may include SiON doped with at least one of H, C, B, and/or As.

In some embodiments, the first through n^{th} bowing prevention buffer layers 32_C1 and 32_C2 through 32_Cn include SiO₁₋ₓNₓ (where 0<X<1), the first through n^{th} bowing sacrificial layers 32_A1 and 32_A2 through 32_An may include SiO₁₋ₓNₓ (where X=0, e.g., SiO₁₋ₓNₓ may include SiO), and the first through n^{th} bowing prevention layers 32_B1 through 32_Bn may include SiO₁₋ₓNₓ (where X=1, e.g., SiO₁₋ₓNₓ may include SiN).

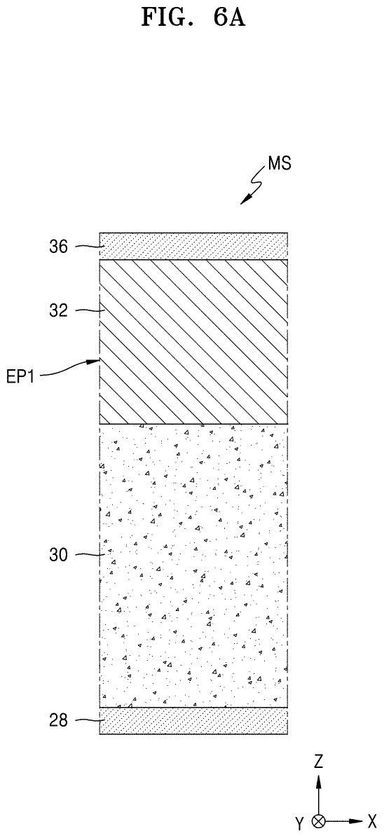

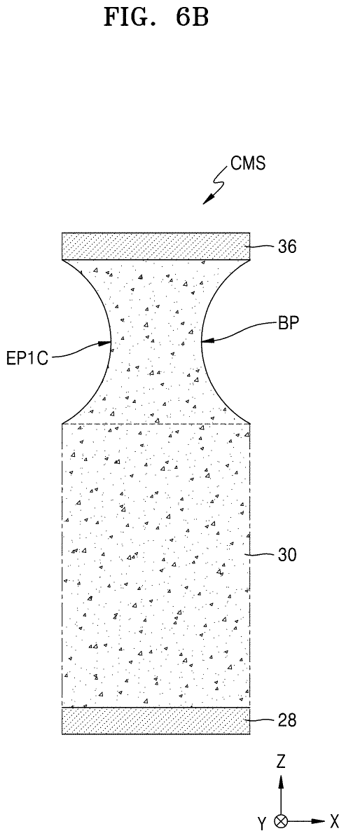

FIGS. 6A and 6B are respectively cross-sectional views of a mold structure according to some example embodiments and a mold structure according to a comparison example.

In detail, FIG. 6A shows the mold structure MS in FIGS. 2 and 3, and FIG. 6B shows a mold structure CMS in a comparative example for comparison with the mold structure MS in FIG. 6A. The mold structure MS, according to the example embodiments in FIG. 6A, may include the upper base mold layer 30, the composite mold layer 32, and the intermediate supporter layer 36, which are on the lower supporter layer 28. In the mold structure MS, an etch concentration may be prohibited due to the composite mold layer 32, and therefore, the bowing portion having the bow shape may be not formed on the sidewall EP1 of the mold structure MS.

On the contrary, the mold structure CMS of the comparison example shown in FIG. 6B may include the upper base mold layer 30 and the intermediate supporter layer 36, which are on the lower supporter layer 28. In the mold structure CMS of the comparison example shown in FIG. 6B, etch concentration may occur at an upper portion of the upper base mold layer 30, and thus, the bowing portion BP having the bow shape may be formed on a sidewall EP1C of the mold structure CMS.

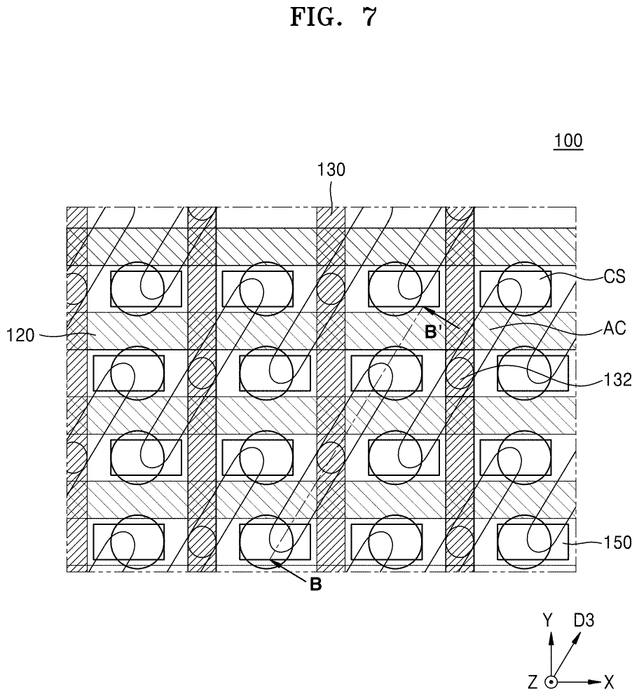

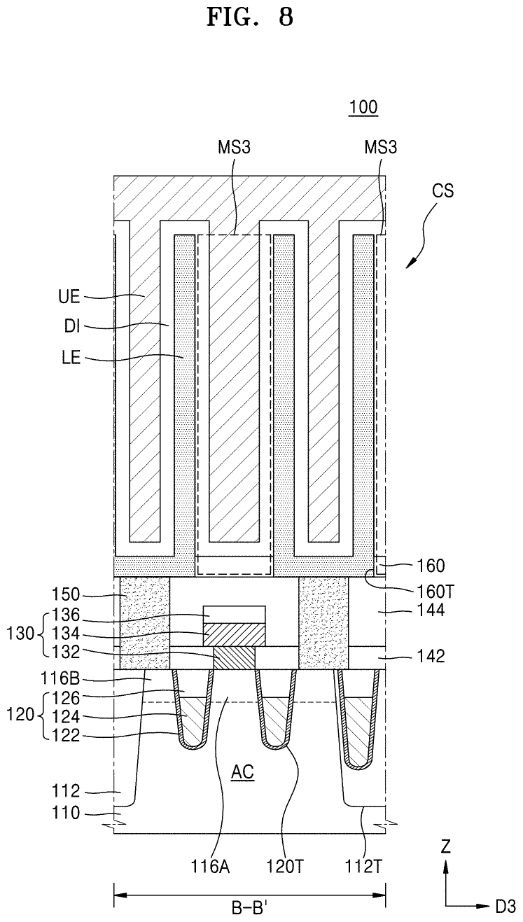

FIG. 7 is a top-plan view of the semiconductor chip included in the semiconductor structure according to some example embodiments, and FIG. 8 is a cross-sectional view taken along line B-B′ shown in FIG. 7.

Referring to FIGS. 7 and 8, a semiconductor chip (and/or a semiconductor device) 100 may correspond to any one of the semiconductor chips 14 formed in the chip region 16 of the semiconductor structure 10 shown in FIG. 1. For example, the semiconductor chip (and/or the semiconductor device) 100 shown in FIGS. 7 and 8 may correspond to any one of the semiconductor chips 14 included in the semiconductor structure 10 shown in FIG. 1.

Here, a structure of the semiconductor chip 100 will be described in further detail. The semiconductor chip 100 may be implemented on a substrate 110. The substrate 110 may correspond to the substrate 12 shown in FIG. 1. The substrate 110 may include an active region AC defined by a device isolation layer 112. In some example embodiments, the substrate 110 may include semiconductor materials such as silicon (Si), germanium (Ge), silicon-germanium (Sg), silicon carbide (SiC), gallium arsenide (GaAs), indium arsenide (InAs), and/or indium phosphite (InP). In some example embodiment, the substrate 110 may include a conductive region, for example, a well doped with impurities, and/or a structure doped with impurities.

The device isolation layer 112 may have a shallow trench isolation (STI) structure. For example, the device isolation layer 112 may include an insulating material, which fills a device isolation trench 112T formed in the substrate 110. The insulating material may include fluoride silicate glass (FSG), undoped silicate glass (USG), boro-phospho-silicate glass (BPSG), phospho-silicate glass (PSG), flowable oxide (FOX), plasma enhanced tetra-ethyl-ortho-silicate (PE-TEOS), and/or a polysilazane (e.g., tonen silazane (TOSZ)), but is not limited thereto.

The substrate 110 may further include an active region AC, which is defined by the device isolation layer 112; and a gate line trench 120T, which may be arranged parallel to the upper surface of the substrate 110 and/or to extend in the X direction. The active regions ACs may each have a relatively long island shape and may have a short axis and a long axis. As illustrated in FIG. 7, the long axis of the active region AC may be arranged in a direction D3 that is parallel to a top surface of the substrate 110. In example embodiments, the active region AC may be doped with P-type impurities or N-type impurities.

The substrate 110 may further include a gate line trench 120T extending in the X direction that is parallel to the top surface of the substrate 110. The gate line trench 120T may cross with the active region AC and may be formed in a certain (or otherwise determined) depth from the top surface of the substrate 110. A portion of the gate line trench 120T may extend into the device isolation layer 112, and the portion of the gate line trench 120 formed in the device isolation layer 112 may have a bottom surface that is at a level lower than that of a portion of the gate line trench 120T formed in the active region AC.

A first source/drain region 116A and a second source/drain region 116B may be at an upper portion of the active region AC at two sides of the gate line trench 120T. The first source/drain region 116A and the second source/drain region 116B may be impurity regions, which are doped with an impurity having a conductive type different from that of an impurity doped on the active region AC. The first source/drain region 116A and the second source/drain region 116B may be doped with N-type or P-type impurities.

A gate structure 120 may be formed in the gate line trench 120T. The gate structure 120 may include a gate insulating layer 122, a gate electrode 124, and a gate capping layer 126 sequentially formed on an inner wall of the gate line trench 120T. The gate insulating layer 122 may be conformally formed in a certain (and/or otherwise determined) thickness on the inner wall of the gate line trench 120T.

The gate insulating layer 122 may include at least one of SiOₓ, SiN, SiON, oxide/nitride/oxide (ONO), and/or a high-k dielectric material (e.g., having a dielectric constant higher than that of SiOₓ). For example, the gate insulating layer 122 may have a dielectric constant from about 10 to about 25. In some embodiments, the gate insulating layer 122 may include hafnium dioxide (HfO₂), zirconium dioxide (ZrO₂), aluminum oxide (Al₂O₃), HfAlO₃, tantalum oxide (Ta₂O₃), titanium dioxide (TiO₂), and/or combinations thereof, but is not limited thereto.

The gate electrode 124 may be formed on the gate insulating layer 122 to fill the gate line trench 120T from a bottom portion of the gate line trench 120T to a certain (and/or otherwise determined) height. The gate electrode 124 may include a work function adjustment layer (not shown) on the gate insulating layer 122, and a buried metal layer (not shown) filling the bottom portion of the gate line trench 120T on the work function adjustment layer. For example, the work function adjustment layer may include a conductive material such as a metal, a metal nitride, and/or a metal carbide. For example, the work function adjustment layer may include at least one of titanium (Ti), titanium nitride (TiN), titanium aluminum nitride (TiAlN), titanium aluminum carbide (TiAlC), titanium aluminum carbon nitride (TiAlCN), titanium silicon carbon nitride (TiSiCN), tantalum (Ta), tantalum nitride (TaN), tantalum aluminum nitride (TaAlN), tantalum aluminum carbon nitride (TaAlCN), and/or tantalum silicon carbon nitride (TaSiCN), and the buried metal layer may include at least one of tungsten (W), tungsten nitride (WN), TiN, and/or TaN.

The gate capping layer 126 may fill, on the gate electrode 126, a remaining portion of the gate line trench 120T. The gate capping layer 126 may include an insulating material. For example, the gate capping layer 126 may include at least one of SiN, SiON, and SiN.

A bit line structure 130 extending in the Y direction, which is parallel to the top surface of the substrate 110 and perpendicular to the X direction, may be formed on the first source/drain region 116A. The bit line structure 130 may include a bit line contact 132, a bit line 134, and a bit line capping layer 136 sequentially stacked on the substrate 110. For example, the bit line contact 132 may include polysilicon, and the bit line 134 may include a metal material. The bit line capping layer 136 may include an insulating material such as SiN or SiON.

Although FIG. 8 illustrates that the bit line contact 132 is formed to have a bottom surface at a same level as that of the top surface of the substrate 110, the example embodiments are not so limited, and a recess (not shown) may be formed in a certain (and/or otherwise determined) depth from the top surface of the substrate 110 and the bit line contact 132 may extend into the recess, and therefore, the bottom surface of the bit line contact 132 may be formed at a level that is lower than that of the top surface of the substrate 110.

Alternatively, a bit line intermediate layer (not shown) may be between the bit line contact 132 and the bit line 134. The bit line intermediate layer may include a metal silicide such as tungsten silicide, and/or a metal nitride such as tungsten nitride. A bit line spacer (not shown) may be further formed above a sidewall of the bit line structure 130. The bit line spacer may have a single-layer structure or a multi-layer structure including an insulating material such as SiOₓ, SiON, and/or SiN. In addition, the bit line spacer may further include an air space (not shown).

A first interlayer insulating layer 142 may be formed above the substrate 110. The bit line contact 132 may penetrate through the first interlayer insulating layer 142 and be connected to the first source/drain region 116A. The bit line 134 and the bit line capping layer 136 may be on the first interlayer insulating layer 142. A second interlayer insulating layer 144 may be arranged, on the first interlayer insulating layer 142, to cover side surfaces and top surfaces of the bit line 134 and the bit line capping layer 136.

A contact structure 150 may be on the second source/drain region 116B. The first interlayer insulating layer 142 and the second interlayer insulating layer 144 may surround a sidewall of the contact structure 150. In some example embodiments, the contact structure 150 may include a lower contact pattern (not shown), a metal silicide layer (not shown), and/or an upper contact pattern (not shown), which are sequentially stacked on the substrate 110. The contact structure 150 may further include a barrier layer (not shown) surrounding a side surface and/or a bottom surface of the upper contact pattern. In some example embodiments, the lower contact pattern may include polysilicon, and the upper contact pattern may include a metal material. The barrier layer may include a conductive metal nitride.

A capacitor CS may be on the second interlayer insulating layer 144. The capacitor CS may include a lower electrode LE electrically connected to the contact structure 150, a dielectric layer DI conformally covering the lower electrode LE, and an upper electrode UE on the dielectric layer DI. An etch stop layer 160, including an opening 160T, may be formed on the second interlayer insulating layer 144, and a bottom portion of the lower electrode LE may be in the opening 160T of the etch stop layer 160.

The capacitor CS may be arranged, in a process of manufacturing the semiconductor chip 100, between mold structures MS3 as indicated in FIG. 8. The mold structure MS3 (not illustrated) may correspond to the mold structure MS shown in FIG. 2. As show in FIG. 8, during the manufacture of the semiconductor chip 100, the mold structure MS3 may be removed except the etch stop layer 160. As described above with reference to FIGS. 1 and 2, the bowing portion having the bow shape is not formed in the mold structure MS3, and therefore, the bowing portion is also not formed in the lower electrode LE. Therefore, in some embodiments, an outer edge of the lower electrode LE may be substantially straight and/or a vertical profile in the Z direction of the lower electrode may be approximately 90 degrees. Accordingly, the capacitor CS may be formed with reliability.

FIG. 7 illustrates that the capacitors CSs are repeatedly arranged in the X direction and the Y direction on the contact structures 150 that are repeatedly arranged in the X direction and the Y direction. However, the example embodiments are not limited thereto, and, unlike in FIG. 7, on the contact structures 150 repeatedly arranged in the X direction and the Y direction, the capacitors CSs may be arranged in a hexagon shape (e.g., a honeycomb structure) and/or an orthogonal shape. A landing pad (not shown) may also be further formed between the contact structures 150 and the capacitors CSs.

On the contact structure 150, the lower electrode LE may be formed in a bottom-closed cylinder shape or a cup shape. The lower electrode LE may include at least one of metals such as ruthenium (Ru), Ti, Ta, niobium (Nb), iridium (Ir), molybdenum (Mo), and/or W; conductive metal nitrides such as TiN, TaN, niobium nitride (NbN), molybdenum nitride (MoN), and/or tungsten nitride (WN); and/or a conductive metal oxide such as iridium oxide.

The dielectric layer DI may be on the lower electrode LE and the etch stop layer 160. The dielectric layer DI may be conformally arranged on the lower electrode LE and the etch stop layer 160. The dielectric layer DI may include a dielectric material, such as a high-k dielectric material (e.g., having a dielectric constant that is higher than that of the SiOₓ). For example, a first dielectric material may include at least one of ZrO₂, Al₂O₃, Al₂O₃—SiO₂, TiO, yittrium oxide, scandium oxide, and/or lanthanium series oxide.

The upper electrode UE may be on the dielectric layer DI. The upper electrode UE may contact the entire top surface of the dielectric layer DI. The upper electrode UE may be formed by using a material included in the lower electrode LD.

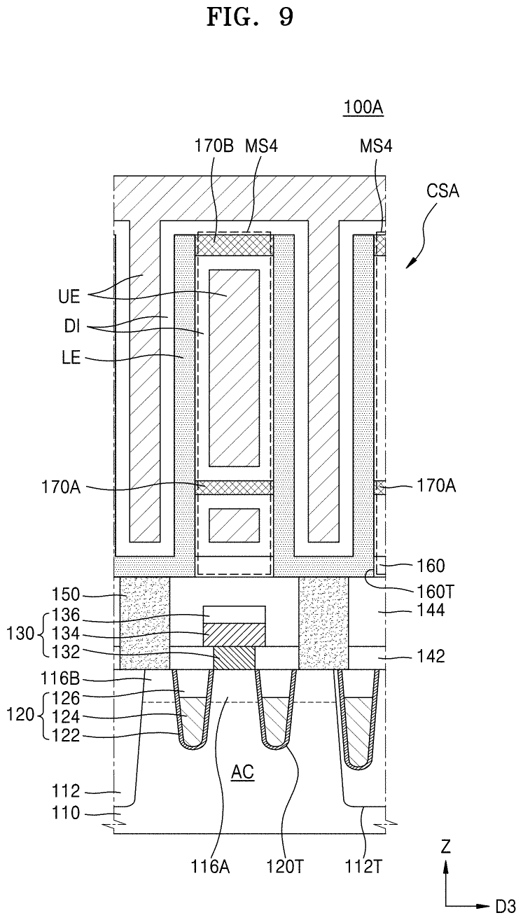

FIG. 9 is a cross-sectional view of a semiconductor chip included in a semiconductor structure according to some example embodiments.

Referring to FIG. 9, compared to the semiconductor chip 100 in FIG. 8, a semiconductor chip 100A may be identical to the semiconductor chip 100, except a capacitor CSA and a mold structure MS4. In FIG. 9, reference numerals that are the same as those of FIG. 8 indicate same components. Therefore, descriptions that are the same as those of FIG. 8 will be briefly given or omitted.

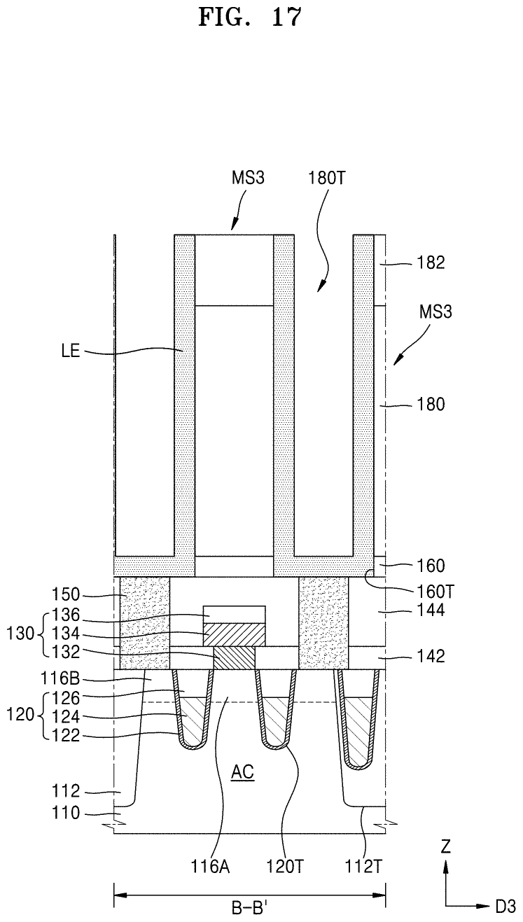

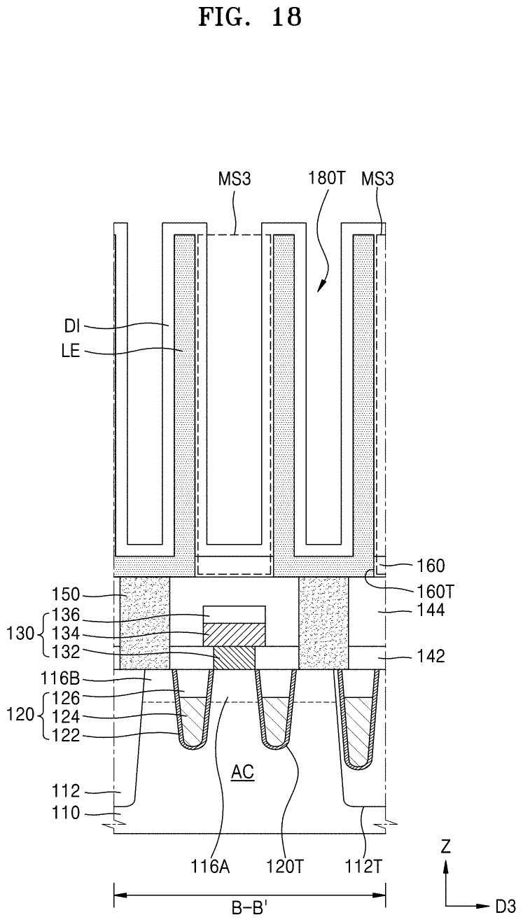

The capacitor CSA may further include a lower supporter layer 170A and an upper supporter layer 170B, which are between the lower electrode LE and a lower electrode LE adjacent thereto. The lower supporter layer 170A and the upper supporter layer 170B may respectively correspond to the lower supporter layer 28 and the upper supporter layer 42 in FIG. 2. The lower supporter layer 170A and the upper supporter layer 170B may prevent (and/or support against) the lower electrode LE (see FIG. 18) from falling down or inclining in a process of etching a base mold layer 180 (see FIG. 17) and a composite mold layer 182 (see FIG. 17) and/or a process of forming the dielectric layer DI (see FIG. 18).

As illustrated in FIG. 9, the upper supporter layer 170B may have a top surface that is coplanar with a top surface of the lower electrode LE, but the example embodiments are not limited thereto. Additionally, though only two support layers (e.g., the lower supporter layer 170A and the upper supporter layer 170B) are illustrated, three or more supporter layers, respectively at different levels, may be on a sidewall of the lower electrode LE.

In a process of manufacturing the semiconductor chip 100A, the capacitor CSA may be between the mold structures MS4, as indicated in FIG. 9. The mold structures MS4 may correspond to the mold structures MS in FIG. 2. During the manufacture of the semiconductor chip 100A, except the etch stop layer 160, the lower supporter layer 170A, and the upper supporter layer 170B, the mold structure MS4 may be removed.

As described above with reference to FIGS. 1 and 2, the bowing portion having the bow shape is not formed in the mold structure MS4, and therefore, the bowing portion is also not formed in the lower electrode LE. Therefore, in some embodiments, an outer edge of the lower electrode LE may be substantially straight and/or a vertical profile in the Z direction of the lower electrode LE may be approximately 90 degrees. Accordingly, the capacitor CSA may be formed with reliability.

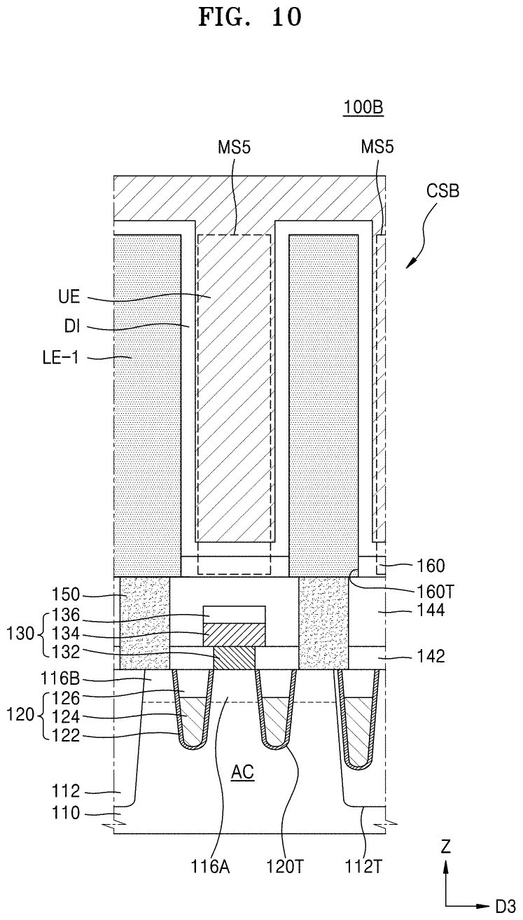

FIG. 10 is a cross-sectional view of a semiconductor chip included in a semiconductor structure according to some example embodiments.

Referring to FIG. 10, compared to the semiconductor chip 100 in FIG. 8, a semiconductor chip 100B may be identical to the semiconductor chip 100 except a capacitor CSB and a mold structure MS5. In FIG. 10, reference numerals that are the same as those of FIG. 8 indicate same components. In FIG. 10, descriptions that are the same as those of FIG. 8 will be briefly given or omitted.

A capacitor CSB may include a lower electrode LE-1 that has a pillar type. A bottom portion of the lower electrode LE-1 is in the opening 160T of the etch stop layer, and the lower electrode LE-1 may have a cylinder, a square pillar, and/or a polygon pillar extending in a vertical direction (the Z direction). The dielectric layer DI may be conformally arranged between the lower electrode LE-1 and the etch stop layer 160.

In a process of manufacturing the semiconductor chip 100B, the capacitor CSB may be between the mold structures MS5 as indicated in FIG. 10. The mold structure MS5 may correspond to the mold structure MS shown in FIG. 2. During the manufacture of the semiconductor chip 100B, the mold structure MS5 may be removed except the etch stop layer 160.

As described above with reference to FIGS. 1 and 2, the bowing portion having the bow shape is not formed in the mold structure MS5, and therefore, the bowing portion is also not formed in the lower electrode LE-1. Therefore, an outer edge of the lower electrode LE may be substantially straight and/or a vertical profile in the Z direction of the lower electrode LE-1 may be approximately 90 degrees. Accordingly, the capacitor CSB may be formed with reliability.

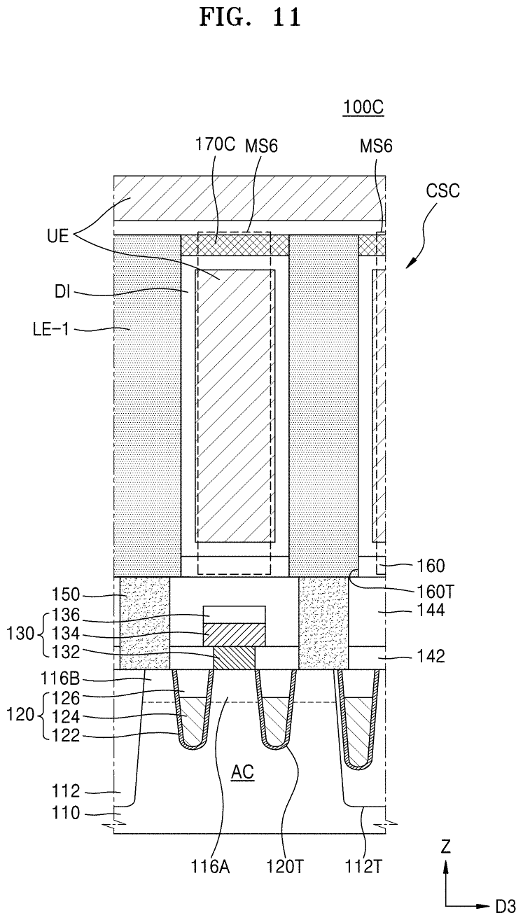

FIG. 11 is a cross-sectional view of a semiconductor chip included in a semiconductor structure according to some example embodiments.

Referring to FIG. 11, and compared to the semiconductor chip 100 in FIG. 8, a semiconductor chip 100C may be identical to the semiconductor chip 100 except a capacitor CSC and a mold structure MS6. In FIG. 11, reference numerals that are the same as those of FIG. 8 indicate same components. In FIG. 11, descriptions that are the same as those of FIG. 8 will be briefly given or omitted.

The capacitor CSC may include the lower electrode LE-1 that has a pillar type. A bottom portion of the lower electrode LE-1 is in the opening 160T of the etch stop layer, and the lower electrode LE-1 may have a cylinder, a square pillar, and/or a polygon pillar extending in a vertical direction (the Z direction). The dielectric layer DI may be conformally arranged on the lower electrode LE-1 and the etch stop layer 160.

An upper supporter layer 170C may be formed on a sidewall of the lower electrode LE-1 and to prevent (and/or mitigate the potential of) the lower electrode LE-1 from inclining and/or falling down. The upper supporter layer 170C may correspond to the upper supporter layer 42 shown in FIG. 2.

In a process of manufacturing the semiconductor chip 100C, the capacitor CSC may be between the mold structures MS6 shown in FIG. 11. The mold structure MS6 may correspond to the mold structure MS shown in FIG. 2. During the manufacture of the semiconductor chip 100C, except the etch stop layer 160 and the upper supporter layer 170C, the mold structure MS6 may be removed.

As described above with reference to FIGS. 1 and 2, the bowing portion having the bow shape is not formed in the mold structure MS6, and therefore, the bowing portion is also not formed in the lower electrode LE-1. Therefore, an outer edge of the lower electrode LE may be substantially straight, and/or a vertical profile in the Z direction of the lower electrode LE-1 may be approximately 90 degrees. Accordingly, the capacitor CSC may be formed with reliability.

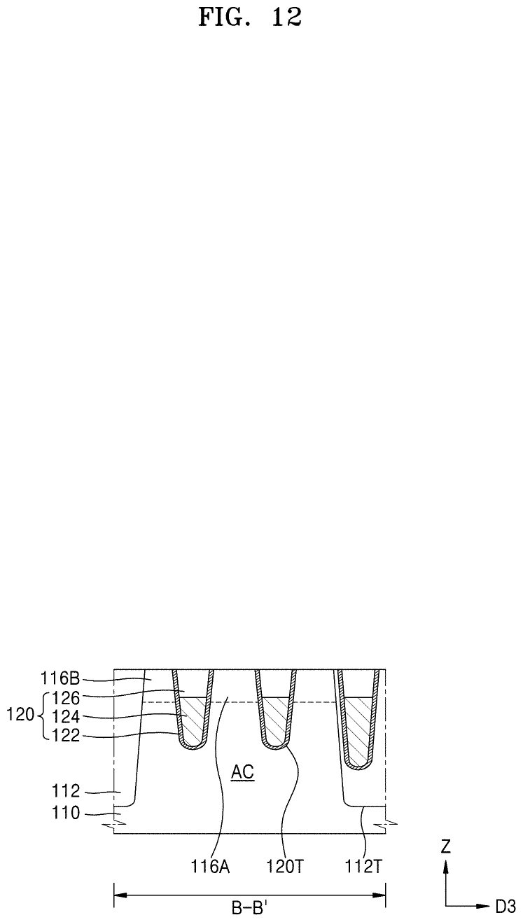

FIGS. 12 through 18 are cross-sectional views for describing a method of manufacturing a semiconductor chip included in a semiconductor structure according to some example embodiments.

Referring to FIGS. 12 through 18, a method of manufacturing the semiconductor chip 100, shown in FIGS. 7 and 8, is illustrated. In FIGS. 12 through 18, reference numerals that are the same as those of FIGS. 7 and 8 indicate same components. In FIGS. 12 through 18, descriptions that are the same as those of FIGS. 7 and 8 will be briefly given or omitted.

Referring to FIG. 12, the device isolation trench 112T may be formed on the substrate 110, and the device isolation layer 112 may be formed in the device isolation trench 112T. An active region AC of the substrate 110 may be defined by the device isolation layer 112.

Thereafter, a first mask (not shown) is formed on the substrate 110, and the gate line trench 120T may be formed in the substrate 110 by using the first mask as an etch mask. The gate line trenches 120Ts may extend in parallel to each other, and may each have a line shape crossing the active region AC.

Thereafter, the gate insulating layer 122 may be formed on the inner wall of the gate line trench 120T. A gate conductive layer (not shown) filling the gate line trench 120T is formed on the gate insulating layer 122, and next, an upper portion of the gate conductive layer is removed to a certain height by an etch-back process, and by doing so, the gate electrode 124 may be formed.

Next, an insulating material is formed to fill a remaining portion of the gate line trench 120T and the insulating material may be smoothed (e.g., planarized) until the top surface of the substrate 110 is exposed, the gate capping layer 126 may be formed on the inner wall of the gate line trench 120T. After doing so, the first mask may be removed.

The first source/drain region 116A and the second source/drain region 116B may be formed (e.g., by impurity ion implantation on the substrate 110 at two sides of the gate structure 120). The first source/drain region 116A and the second source/drain region 116B may be formed on the active region AC before or after forming the device isolation layer 112.

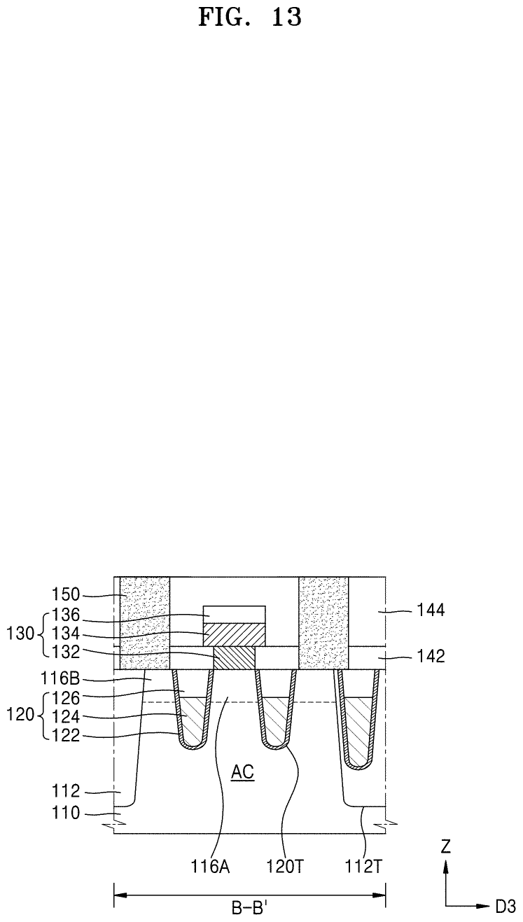

Referring to FIG. 13, a first interlayer insulating layer 142 may be formed on the substrate 110, and an opening that exposes a top surface of the first source/drain region 116A may be formed in the first interlayer insulating layer 142. The bit line contact 132 electrically connected to the first source/drain region 116A may be formed in the opening by forming a conductive layer (not shown) filling the opening on the first interlayer insulating layer 142 and smoothing the upper portion of the conductive layer.

Next, the bit line capping layer 136 and the bit line 134 may be formed by sequentially forming the conductive layer (not shown) and an insulating layer (not shown) on the first interlayer insulating layer 142 and patterning the insulating layer and the conductive layer. Although not shown, a bit line spacer (not shown) may be further formed on sidewalls of the bit line 134 and the bit line capping layer 136.

Next, the second interlayer insulating layer 144, which may cover the bit line 134 and the bit line capping layer 136, may be formed on the first interlayer insulating layer 142. Next, an opening exposing a top surface of the second source/drain region 116B may be formed in the first interlayer insulating layer 142 and the second interlayer insulating layer 144, and the contact structure 150 may be formed in the opening. In some example embodiments, the contact structure 150 may be formed by sequentially forming a lower contact pattern (not shown), a metal silicide layer (not shown), a barrier layer (not shown), and an upper contact pattern (not shown) in the opening.

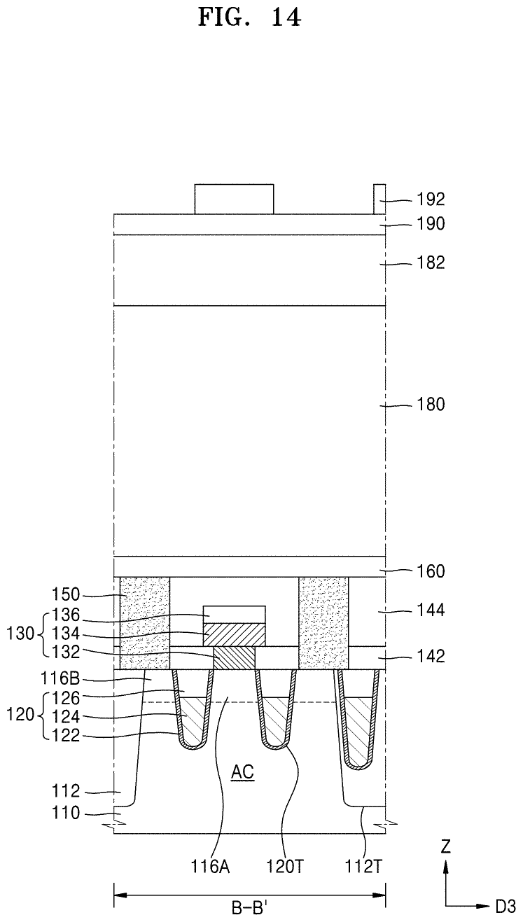

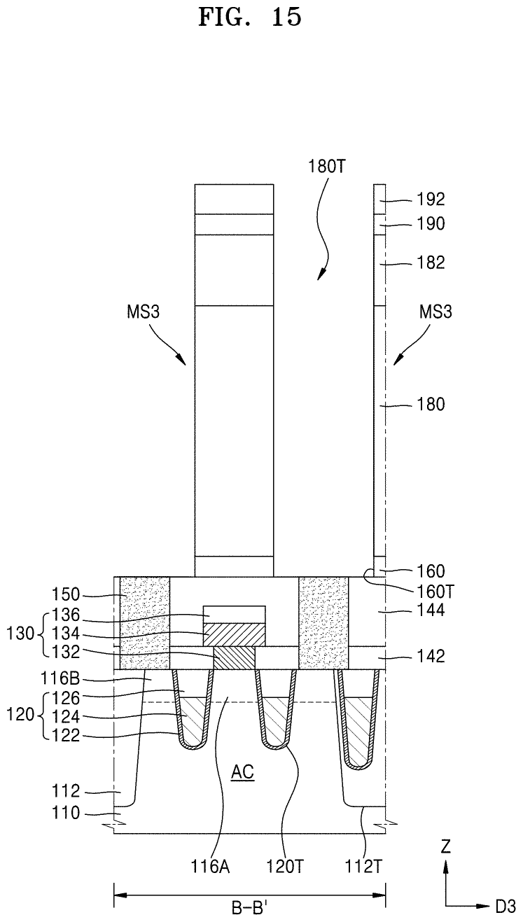

Referring to FIG. 14, the etch stop layer 160, the base mold layer 180, the composite mold layer 182, a sacrificial layer 190, and a mask pattern 192 may be sequentially formed on the second interlayer insulating layer 144 and the contact structure 150. The base mold layer 180 may correspond to the lower base mold layer 24 and the upper base mold layer 30 shown in FIG. 2. The composite mold layer 182 may correspond to the composite mold layer 32 shown in FIG. 2.

In example embodiments, the base mold layer 180, the composite mold layer 182, and the etch stop layer 160 may include materials having an etching selectivity with respect to one another. In addition, the base mold layer 180, the composite mold layer 182, and the sacrificial layer 190 may include materials having an etching selectivity with respect to one another.

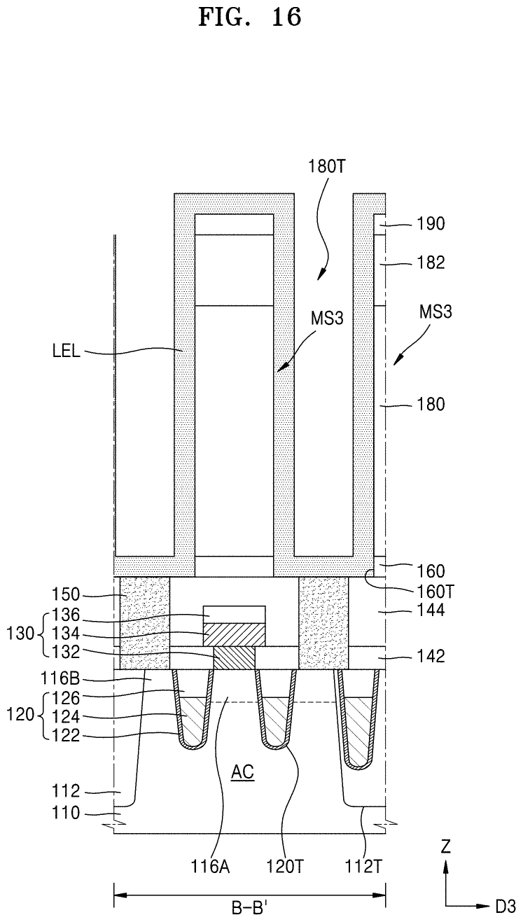

Referring to FIG. 15, an opening 180T may be formed by sequentially etching the sacrificial layer 190, the composite mold layer 182, and the base mold layer 180 by using the mask pattern 192. The opening 180T may correspond to the opening (e.g., the first opening 26, the second opening 34, and the third opening 40) shown in FIG. 2.

Next, the opening 160T may be formed by removing the etch stop layer 160 exposed on a bottom of the opening 180T. A top surface of the contact structure 150 may be exposed by the opening 180T and the opening 160T. Structures that have the opening 180T and the opening 160T exposing the contact structure 150 (e.g., the sacrificial layer 190, the composite mold layer 182, the base mold layer 180, and the etch stop layer 160) may correspond to the mold structure MS3 shown in FIG. 8.

As described above, due to the composite mold layer 182, the bowing portion having the bow shape may be not formed on a sidewall of the mold structure MS3 (e.g., a sidewall of the composite mold layer 182 and/or the base mold layer 180). Therefore, an outer edge of the composite mold layer 182 and the base mold layer may be substantially straight and/or the vertical profiles in the Z direction of the composite mold layer 182 and the base mold layer 180 may be approximately 90 degrees.

Referring to FIG. 16, the mask pattern 192 (see FIG. 15) may be removed. Next, a preliminary lower electrode layer LEL may be formed on the etch stop layer 160, the base mold layer 180, the composite mold layer 182, and the sacrificial layer 190 to conformally cover inner walls of the opening 180T and the opening 160T. The preliminary lower electrode layer LEL may be formed to cover the mold structure MS3. The preliminary lower electrode layer LEL may be formed by using a deposition process (e.g., CVD process, a metalorganic CVD (MOCVD) process, an atomic layer deposition (ALD) process, and/or a metalorganic ALD (MOALD) process).

Referring to FIG. 17, the lower electrode LE may be formed by removing a portion of the preliminary lower electrode layer LEL (see FIG. 16) and the sacrificial layer 190, which are on a top surface of the composite mold layer 182, by, for example, an etch-back process. The composite mold layer 182 included in the mold structure MS3 may be exposed. The lower electrode LE may be formed between the mold structures MS3s.

As described above, the bowing portion having the bow shape is not formed in the mold structure MS3, and therefore, the bowing portion is also not formed in the lower electrode LE. Therefore, an outer edge of the lower electrode LE may be substantially straight and/or a vertical profile in the Z direction of the lower electrode may be approximately 90 degrees.

Referring to FIG. 18, the composite mold layer 18 (see FIG. 17) and the base mold layer 180 (see FIG. 17) may be removed. In a process of removing the composite mold layer 182 (see FIG. 17) and the base mold layer 180 (see FIG. 17), the etch stop layer 160 may remain without being removed. For example, among components included in the mold structure MS3, in some embodiments only the etch stop layer 160 remains. The lower electrode LE may be on the contact structure 150 and be formed in a bottom-closed cylinder shape.

Continuously, as shown in FIG. 8, the capacitor CS is formed by sequentially forming the dielectric layer DI and the upper electrode UE on the lower electrode LE and the etch stop layer 160. The dielectric layer DI and/or the upper electrode UE may be formed by a deposition process (e.g., the CVD process, the MOCVD process, the ALD process, the MOALD process, and/or the like). As described above, an outer edge of the lower electrode LE may be substantially straight and/or a vertical profile of the lower electrode LE in the Z direction is approximately 90 degrees, and therefore, the capacitor CS may be formed with reliability. The semiconductor chip 100 (see FIGS. 7 and 8) may be completed by performing the above-described processes.

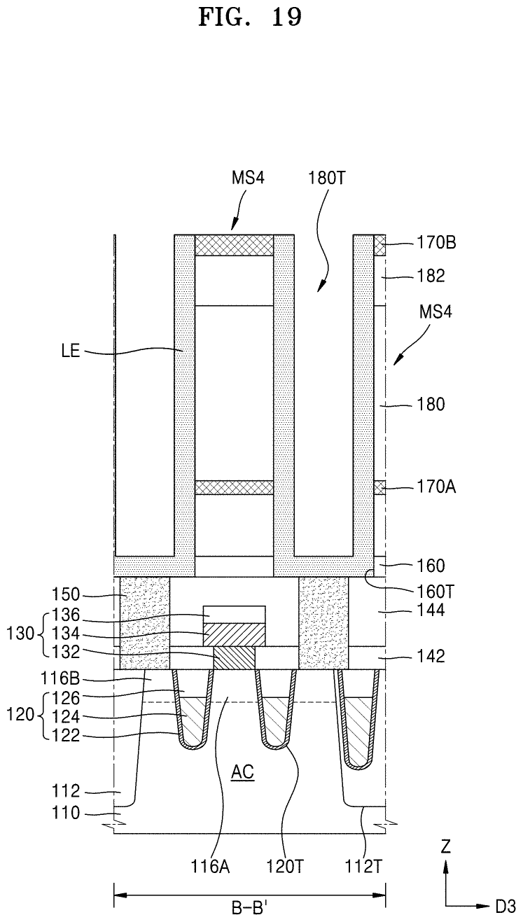

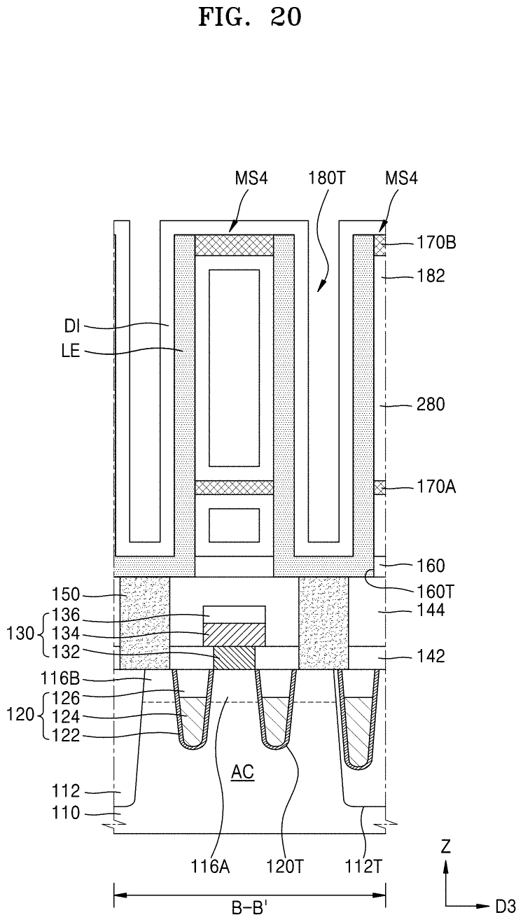

FIGS. 19 and 20 are cross-sectional views for describing a method of manufacturing a semiconductor chip included in a semiconductor structure according to some example embodiments.

Referring to FIGS. 19 and 20, a method of manufacturing the semiconductor chip 100A shown in FIG. 9 is illustrated. Except the mold structure MS4, FIGS. 19 and 20 may be identical to FIGS. 12 through 18. In FIGS. 19 and 20, reference numerals that are the same as those of FIGS. 12 and 18 indicate same components. In FIGS. 19 and 20, descriptions that are the same as those of FIGS. 12 through 18 are briefly described or omitted.

Referring to FIG. 19, except the mold structure MS4, the manufacturing processes in FIGS. 12 through 17 are performed. The mold structure MS4 may include the etch stop layer 160, the lower supporter layer 170A, the base mold layer 180, the composite mold layer 182, and the upper supporter layer 170B. For example, the mold structure MS4 may be a structure that has the opening 180T and the opening 160T exposing the contact structure 150 (e.g., the upper supporter layer 170B, the composite mold layer 182, the base mold layer 180, the lower supporter layer 170A, and the etch stop layer 160).

As described above, due to the composite mold layer 182, the bowing portion having the bow shape may be not formed on a sidewall of the mold structure MS4, (e.g., the sidewall of the composite mold layer 182 or the base mold layer 180). Therefore, an outer edge of the mold structure MS4 may be substantially straight and/or vertical profiles in the Z direction of the composite mold layer 182 and the base mold layer 180 may be approximately 90 degrees.

Next, the lower electrode LE is formed on the etch stop layer 160, the lower supporter layer 170A, the base mold layer 180, the composite mold layer 182, and the upper supporter layer 170B to conformally cover the inner walls of the opening 180T and the opening 160T. As described above, the bowing portion having the bow shape is not formed in the mold structure MS4, and therefore, the bowing portion is also not formed in the lower electrode LE. Therefore, an outer edge of the lower electrode LE may be substantially straight and/or a vertical profile in the Z direction of the lower electrode may be approximately 90 degrees. A process of forming the lower electrode LE may be performed after the manufacturing processes shown in FIGS. 16 and 17.

Referring to FIG. 20, the composite mold layer 182 (see FIG. 19) and the base mold layer 180 (see FIG. 19) may be removed. In a process of removing the composite mold layer 182 (see FIG. 19) and the base mold layer 180 (see FIG. 19), the etch stop layer 160, the lower supporter layer 170A, and the upper supporter layer 170B may remain without being removed. Therefore, in some embodiments, among components included in the mold structure MS4, only the etch stop layer 160, the lower supporter layer 170A, and the upper supporter layer 170B remain. Though FIG. 20 is illustrated as including a cup-shape for the lower electrode LE, the lower electrode LE may be on the contact structure 150 and be formed in a bottom-closed cylinder shape.

Continuously, as shown in FIG. 9, the capacitor CSA is formed by forming the dielectric layer DI and the upper electrode UE on the lower electrode LE, the etch stop layer 160, the lower supporter layer 170A, and the upper supporter layer 170B. As described above, an outer edge of the lower electrode LE may be substantially straight and/or a vertical profile of the lower electrode LE in the Z direction is approximately 90 degrees, and therefore, the capacitor CS may be formed with reliability. The semiconductor chip 100A (see FIG. 9) may be completed by performing the above-described processes.

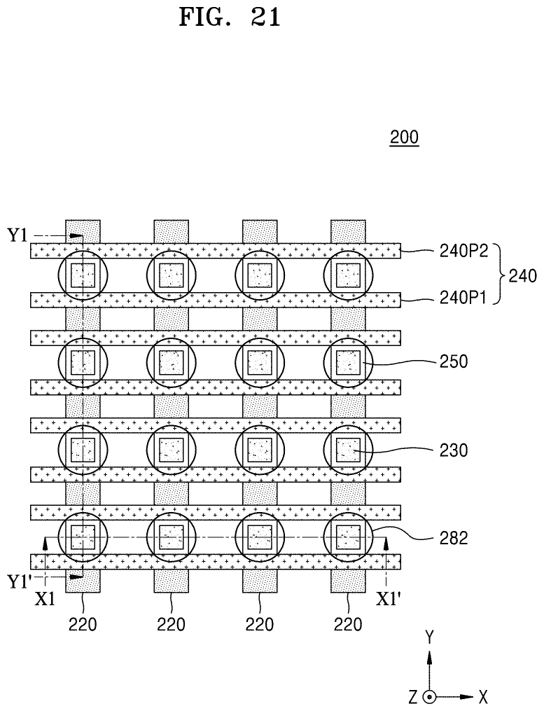

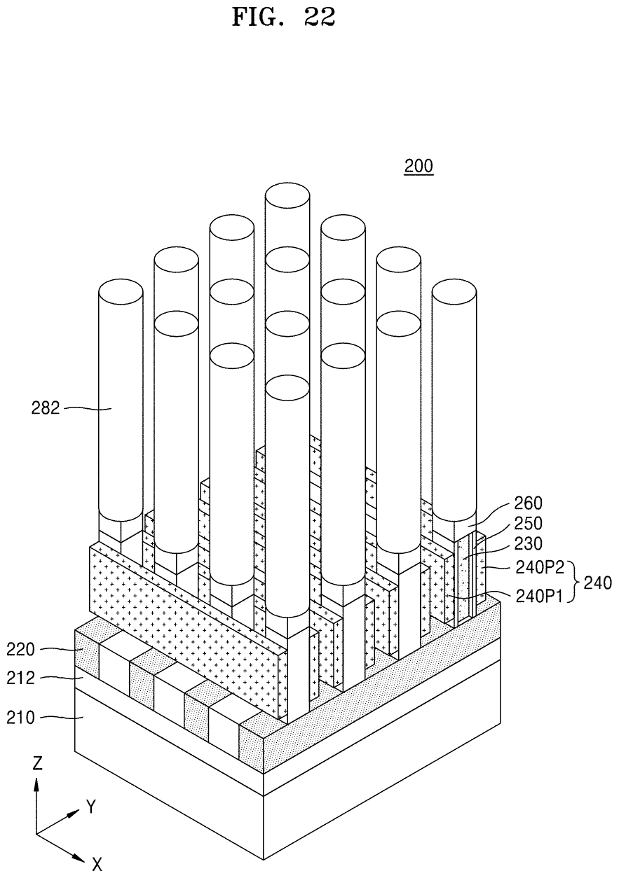

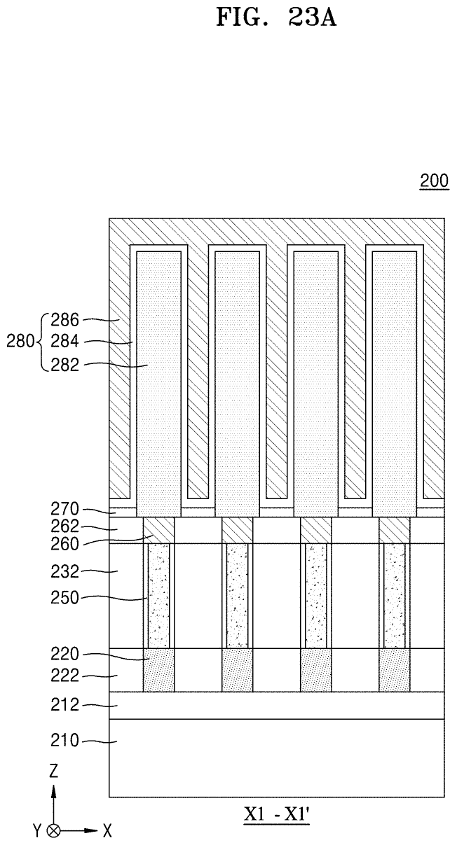

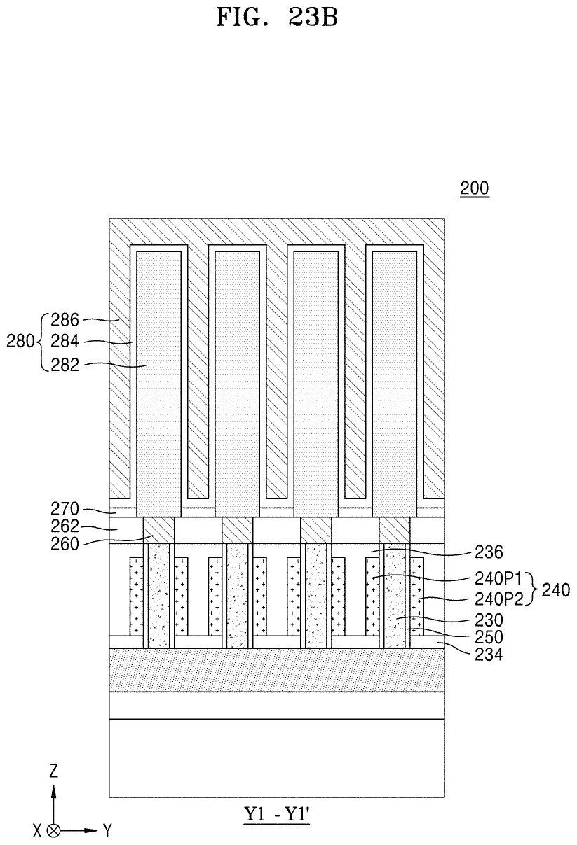

FIG. 21 is a top-plan view of a semiconductor chip included in a semiconductor structure according to some example embodiments, FIG. 22 is a perspective view of the semiconductor chip shown in FIG. 21, and FIGS. 23A and 23B are cross-sectional views respectively taken along lines X1-X1′ and Y1-Y1′ shown in FIG. 21.

Referring to FIGS. 21 to 23B, a semiconductor chip (or a semiconductor device) 200 may correspond to any one of the semiconductor chips 14 formed in the chip region 16 of the semiconductor structure 10 in FIG. 1. For example, the semiconductor chip (or the semiconductor device) 200 may correspond to any one of the semiconductor chips 14 included in the semiconductor structure 10 shown in FIG. 1. The semiconductor chip 200 may be referred to as an integrated circuit device. Here, a structure of the semiconductor chip 200 is described in further detail.

Referring to FIGS. 21, 22, 23A, and 23B, the semiconductor chip 200 may include a substrate 210, a plurality of first conductive lines 220, a channel layer 230, a gate electrode 240, a gate insulating layer 250, and a capacitor 280. The semiconductor chip 200 may include a memory device including a vertical channel transistor (VCT). The VCT may have a structure in which a channel length of the channel layer 230 extends in a vertical direction from the substrate 210.

A lower insulating layer 212 may be on the substrate 210, and on the lower insulating layer 212, the plurality of first conductive lines 220 may be separated from one another in a first direction (e.g., the X direction) and extend in a second direction (e.g., the Y direction). On the lower insulating layer 212, a plurality of insulating patterns 222 may fill spaces among the plurality of first conductive lines 220. The plurality of first insulating patterns 222 may extend in the second direction (the Y direction), and top surfaces of the plurality of first insulating patterns 222 may be at a same level with top surfaces of the plurality of first conductive lines 220. The plurality of first conductive lines 222 may function as bit lines of the semiconductor chip 200.

In some example embodiments, the plurality of first conductive lines 220 may include doped polysilicon, a metal, a conductive metal nitride, a conductive metal silicide, a conductive metal oxide, and/or combinations thereof. For example, the plurality of first conductive lines 220 may include doped polysilicon, Al, copper (Cu), Ti, Ta, Ru, W, Mo, platinum (Pt), nickel (Ni), cobalt (Co), TiN, TaN, WN, NbN, TiAl, TiAlN, titanium silicide (TiSi), titanium silicon nitride (TiSiN), tantalum silicide (TaSi), tantalum silicon nitride (TaSiN), ruthenium titanium nitride (RuTiN), nickel silicide (NiSi), cobalt silicide (CoSi), iridium oxide (IrOx), ruthenium oxide (RuOx), and/or combinations thereof, but is not limited thereto. The plurality of first conductive lines 220 may include a single-layer and/or a multi-layer of the above-stated materials. In some example embodiments, the plurality of first conductive lines 220 may include a two-dimensional semiconductor material, and for example, the two-dimensional semiconductor material may include graphene, carbon nanotube, molybdenum disulfide (MoS₂), or a combination thereof.

On the plurality of first conductive lines 220 the channel layers 230 may be arranged in the form of a matrix, in which the channel layers 230 are apart from one another in the first direction (the X direction) and the second direction (the Y direction). The channel layer 230 may, when viewed in a plan view, have a first height according to the first direction (the X direction) and a first width according to the third direction (the Z direction), and the first height may be greater than the first width. For example, the first height may be twice to ten times the first width, but is not limited thereto. A bottom portion of the channel layer 230 may function as a first source/drain region (not shown), an upper portion of the channel layer 230 may function as a second source/drain region (not shown), and a portion of the channel layer 230 between the first source/drain region and the second source/drain region may function as a channel region (not shown).

In example embodiments, the channel layer 230 may include an oxide semiconductor, and may include, for example, at least one of InxGayZnzO, InxGaySizO, InxSnyZnzO, InxZnyO, ZnxO, ZnxSnyO, ZnxOyN, ZrxZnySnzO, SnxO, HfxInyZnzO, GaxZnySnzO, AlxZnySnzO, YbxGayZnzO, InxGayO, and/or combinations thereof. The channel layer 230 may include a single layer and/or a multi-layer of the oxide semiconductor.

In some examples, the channel layer 230 may have a bandgap energy that is greater than a bandgap energy of silicon. For example, the channel layer 230 may have a bandgap energy from about 1.5 eV to about 5.6 eV. For example, the channel layer 230 may have the optimal channel performance when the bandgap energy of the channel energy 230 is from about 2.0 eV to about 4.0 eV.

In some example embodiments, the channel layer 230 may be polycrystalline and/or amorphous, but is not limited thereto. In example embodiments, the channel layer 230 may include a two-dimensional semiconductor material, and for example, the two-dimensional semiconductor material may include graphene, carbon nanotube, MoS₂, and/or a combination thereof.

The gate electrode 240 may extend in the first direction (the X direction) on two sidewalls of the channel layer 230. The gate channel 240 may include a first sub gate electrode 240P1, which faces a first sidewall of the channel layer 230, and a second sub gate electrode 240P2, which faces a second sidewall of the channel layer 230 opposite to the first sidewall of the channel layer 230. As one channel layer 230 is between the first sub gate electrode 240P1 and the second sub gate electrode 240P2, the semiconductor chip 200 may have a dual-gate transistor structure. However, the inventive concepts are not limited thereto, and the second sub gate electrode 240P2 may be omitted and only the first sub gate electrode 240P1 facing the first sidewall of the channel layer 230 may be formed, and thus, a single-gate transistor structure may be implemented.

The gate electrode 240 may include a conductive material such as a doped polysilicon, a metal, a conductive metal nitride, a conductive metal silicide, a conductive metal oxide, and/or combinations thereof. For example, the gate electrode 240 may include doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, and/or combinations thereof, but is not limited thereto.

The gate insulating layer 250 may surround a sidewall of the channel layer 230 and may be between the channel layer 230 and the gate electrode 240. For example, as shown in FIG. 21, all sidewalls of the channel layer 230 may be surrounded by the gate insulating layer 250, and a portion of a sidewall of the gate electrode 240 may contact the gate insulating layer 250. In other embodiments, the gate insulating layer 250 may extend in a direction in which the gate electrode 240 extends (e.g., the first direction (the X direction)), and among the sidewalls of the channel layer 230, only two sidewalls facing the gate electrode 240 may contact the gate insulating layer 250.

In some example embodiments, the gate insulating layer 250 may include a silicon oxide film, a silicon oxynitride film, a high-k dielectric film having a dielectric constant that is greater than that of the silicon oxide film, and/or combinations thereof. The high-k dielectric film may include a metal oxide and/or a metal oxynitride. For example, the high-k dielectric film that may be used as the gate insulating layer 250 may include at least one of HfO₂, HfSiO, HfSiON, HfTaO, HfTiO, HfZrO, ZrO₂, Al₂O₃, and/or combinations thereof, but is not limited thereto.

On the plurality of first insulating patterns 222, a plurality of second insulating patterns 232 may extend in the second direction (the Y direction), and the channel layer 230 may be between two second insulating patterns 232 adjacent to each other among the plurality of second insulating patterns 232. Furthermore, between the two second insulating patterns 232 adjacent to each other, a first buried layer 234 and a second buried layer 236 may be in a space between two channel layers 230 adjacent to each other. The first buried layer 234 may be in a bottom portion of the space between the two channel layers 230 adjacent to each other, and the second buried layer 236 may fill, on the first buried layer 234, a remaining portion of the space between the two channel layers 230 adjacent to each other. An upper surface of the second buried layer 236 may be at a level that is the same as an upper surface of the channel layer 230, and the second buried layer 236 may cover an upper surface of the gate electrode 240. Alternatively, the plurality of second insulating patterns 232 may be formed of a material layer that is continued from the plurality of first insulating patterns 222, or the second buried layer 236 that is continued from the first buried layer 234.

Capacitor contacts 260 may be on the channel layers 230. The capacitor contacts 260 may vertically overlap the channel layers 230, and may be arranged in the form of a matrix, in which the capacitor contacts 260 are apart from one another in the first direction (the X direction) and the second direction (the Y direction). The capacitor contact 260 may include a conductive material such as doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, and/or combinations thereof, but is not limited thereto. An upper insulating layer 262 may surround a sidewall of the capacitor contact 260 on the plurality of second insulating patterns 232 and the second buried layer 236.

An etch stop layer 270 may be on the upper insulating layer 262, and a capacitor 280 may be on the etch stop layer 270. The capacitor 280 may include a lower electrode 282, a dielectric layer 284, and an upper electrode 286.

The lower electrode 282 may penetrate the etch stop layer 270 and may be electrically connected to an upper surface of the capacitor contact 260. The lower electrode 282 may be formed in a pillar type extending in the third direction (e.g., the Z direction), but is not limited thereto. In example embodiments, the lower electrodes 282 may vertically overlap the capacitor contacts 260, and may be arranged in the form of a matrix, in which the lower electrodes 282 are apart from one another in the first direction (the X direction) and the second direction (the Y direction). Alternatively, a landing pad (not shown) may be further arranged between the capacitor contacts 260 and the lower electrode 282s, and therefore, the lower electrodes 282 may be arranged in a hexagon shape. As described above, a vertical profile of the lower electrode 282 in the Z direction may be approximately 90 degrees. Accordingly, the capacitor 280 may be formed with reliability.

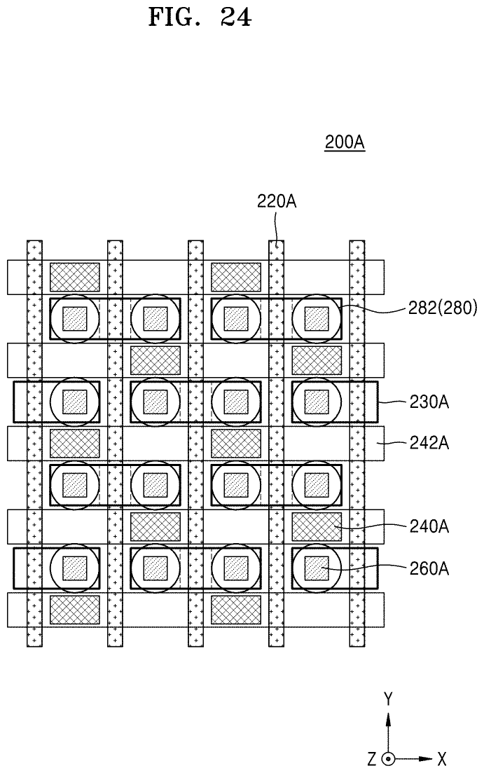

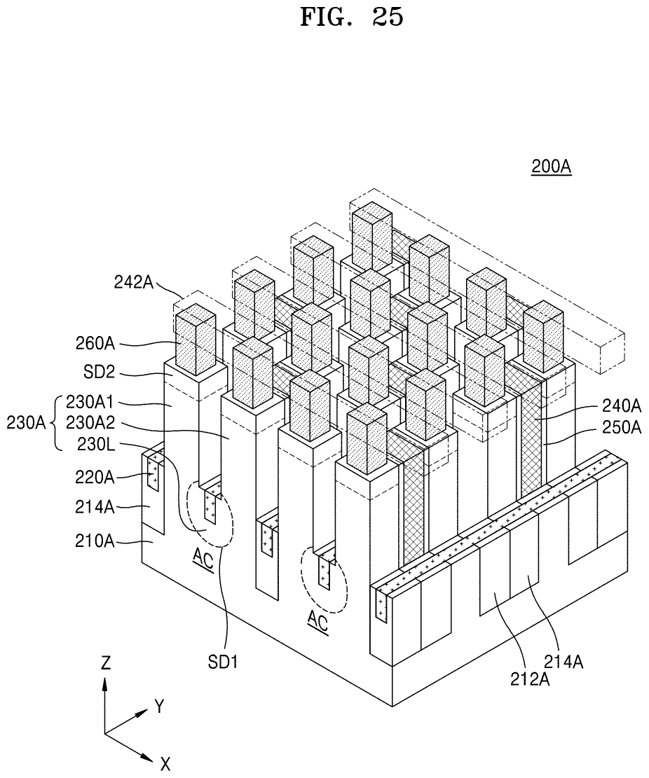

FIG. 24 is a top-plan view of a semiconductor chip included in a semiconductor structure according to some example embodiments, and FIG. 25 is a perspective view of the semiconductor chip shown in FIG. 24.

Referring to FIGS. 24 and 25, a semiconductor chip (or a semiconductor device) 200A may correspond to any one of the semiconductor chips 14 formed in the chip region 16 of the semiconductor structure 10 shown in FIG. 1. The semiconductor chip (or the semiconductor device) 200A may correspond to any one of the semiconductor chips 14 included in the semiconductor structure 10 shown in FIG. 1. The semiconductor chip 200A may be referred to as an integrated circuit device. Here, a structure of the semiconductor chip 200A is described in further detail.

The semiconductor chip 200A may include a substrate 210A, a plurality of first conductive lines 220A, a channel structure 230A, a contact gate electrode 240A, a plurality of second conductive lines 242A, and the capacitor 280. The semiconductor chip 200A may include a memory device including the VCT.

A plurality of active regions ACs of the substrate 210A may be defined by a first device isolation layer 212A and a second device isolation layer 214A. A channel structure 230A may be in each of the active regions AC, and may include a first active pillar 230A1 and a second active pillar 230A2, which respectively extend in the vertical direction, a bottom portion of the first active pillar 230A1, and a link portion 230L linked to a bottom portion of the second active pillar 230A2. A first source/drain region SD1 may be in the link portion 230L, and a second source/drain region SD2 may be on the first active pillar 230A1 and the second active pillar 230A2. The first active pillar 230A1 and the second active pillar 230A2 may each construct an independent unit memory cell.

The plurality of first conductive lines 220A may extend in a direction crossing with the respective active regions AC, and may extend, for example, in the second direction (e.g., the Y direction). Among the plurality of first conductive lines 220A, one first conductive line 220A may be on the link portion 230L between the first active pillar 230A1 and the second active pillar 230A2, and the one first conductive line 220A may be on the first source/drain region SD1. Another first conductive line 220A adjacent to the one first conductive line 220A may be between two channel structures 230A. Among the plurality of first conductive lines 220A, one first conductive line 220A may function as a common bit line included in the two unit memory cells, which are constructed by the first active pillar 230A1 and the second active pillar 230A2 at two sides of the one first conductive line 220A.

One contact gate electrode 240A may be between two channel structures 230A that are adjacent to each other in the second direction (the Y direction). For example, the contact gate electrode 240A may be between the first active pillar 230A1 included in one channel structure 230A and the second active pillar 230A2 of a channel structure 230A adjacent to the one channel structure 230A, and the one contact gate electrode 240 may be shared by the first active pillar 230A1 and the second active pillar 230A2 on two sidewalls thereof. The gate insulating layer 250A may be between the contact gate electrode 240A and the first active pillar 230A1 and between the contact gate electrode 240A and the second active pillar 230A2. The plurality of second conductive lines 242A may extend in the first direction (the X direction) on upper surfaces of the contact gate electrodes 240A. The plurality of second conductive lines 242A may function as word lines of the semiconductor chip 200A.

A capacitor contact 260A may be on the channel structure 230A. The capacitor contact 260A may be on the second source/drain region SD2, and the capacitor 280 may be on the capacitor contact 260A. The capacitor 280 may include the lower electrode 282, the dielectric layer 284 (see FIGS. 22, 23A, and 23B), and the upper electrode 286 (see FIGS. 22, 23A, and 23B). As described above, an outer edge of the lower electrode 282 may be substantially straight and/or a vertical profile of the lower electrode 282 in the Z direction may be approximately 90 degrees. Accordingly, the capacitor 280 may be formed with reliability.

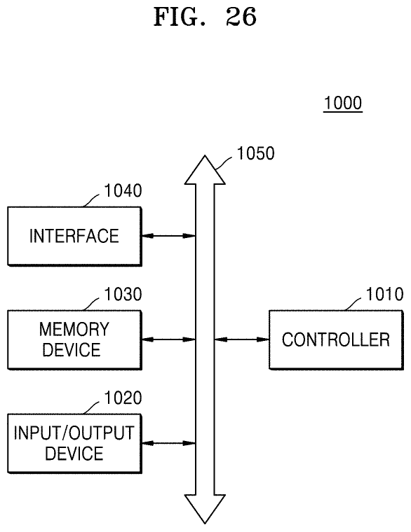

FIG. 26 is a system including a semiconductor chip that is included in a semiconductor structure according to some example embodiments.

Referring to FIG. 26, a system 1000 may include a controller 1010, an input/output device 1020, a memory device 1030, a bus 1050, and/or an interface 1040. The system 1000 may be a system configured to transmit and/or receive information and/or or may be (and/or be included in) a mobile system. In some embodiments, the mobile system may include a personal digital assistant (PDA), a portable computer, a web tablet, a wireless phone, a mobile phone, a digital music player, and/or a memory card.

The controller 1010 is configured to control programs executed in and/or by the system 1000, and may include a microprocessor, a digital signal processor, a microcontroller, or other similar devices. The input/output device 1020 may be used to input and/or output data of the system 1000. In some embodiments, the system 1000 may exchange data with the external device. In some embodiments, the input/output device 1020 may include, for example, a keypad, a keyboard, and/or a display.

The memory device 1030 may store a code and/or data for operations of the controller 1010, and/or may store data processed by the controller 1010. The memory device 1030 may include a semiconductor chip included in the semiconductor structure according to the inventive concepts. The interface 1040 may be a data transmission path between the system 1000 and another external device. In some embodiments, the system 1000 may be linked to an external device (e.g., a personal computer and/or a network) through the interface 1040. The controller 1010, the input/output device 1020, the memory 1030, and the interface 1040 may communicate with one another through the bus 1050.

The system 1000 may be used, for example, in a mobile phone, an MP3 player, a navigation device, a portable multimedia player (PMP), a solid state disk (SSD), and/or household appliances.

While the inventive concepts have been particularly shown and described with reference to some example embodiments thereof, it will be understood that various changes in form and details may be made therein without departing from the spirit and scope of the following claims.

What is claimed is:

1. A semiconductor structure on a substrate, the semiconductor structure comprising:
a chip region comprising a plurality of semiconductor chips on the substrate; and
a peripheral region at a periphery of the chip region, the peripheral region including a mold structure,
wherein the mold structure comprises
a base mold layer on the substrate, and
a composite mold layer on the base mold layer, the composite mold layer comprising at least one bowing sacrificial layer and at least one bowing prevention layer.

2. The semiconductor structure of claim 1, wherein
the at least one bowing sacrificial layer includes a plurality of bowing sacrificial layers,
the at least one bowing prevention layer includes a plurality of bowing prevention layers, and
the plurality of bowing sacrificial layers and the plurality of bowing prevention layers are alternatingly stacked in the composite mold layer.

3. The semiconductor structure of claim 1, wherein
the base mold layer is thicker, in a first direction, than the at least one bowing sacrificial layer, the first direction perpendicular to an upper surface of the substrate, and
the based mold layer comprises a material that is the same as that of the at least one bowing sacrificial layer and different from that of the at least one bowing prevention layer.

4. The semiconductor structure of claim 1, wherein
the at least one bowing sacrificial layer comprises at least one of silicon oxide, silicon oxynitride, or silicon oxide doped with a non-metal element, and
the at least one bowing prevention layer comprises at least one of silicon nitride or a silicon nitride doped with a non-metal element.

5. The semiconductor structure of claim 1, further comprising:
a bowing prevention buffer layer between the at least one bowing sacrificial layer and the at least one bowing prevention layer.

6. The semiconductor structure of claim 1, wherein
the at least one bowing sacrificial layer includes a first bowing sacrificial layer and a second bowing sacrificial layer,
the at least one bowing prevention layer includes a first bowing prevention layer and a second bowing prevention layer, and
the composite mold layer comprises
a first bowing prevention composite layer including the first bowing sacrificial layer and the first bowing prevention layer, and
a second bowing prevention composite layer on the first bowing prevention composite layer, the second bowing prevention composite layer including the second bowing sacrificial layer and the second bowing prevention layer.

7. The semiconductor structure of claim 6, further comprising:
a bowing prevention buffer layer between the first bowing prevention layer and the second bowing sacrificial layer.

8. The semiconductor structure of claim 7, wherein, in the composite mold layer, a plurality of first bowing prevention composite layers, a plurality of bowing prevention buffer layers, and a plurality of second bowing composite layers are sequentially stacked on the base mold layer.

9. The semiconductor structure of claim 7, wherein
the first bowing sacrificial layer and the second bowing sacrificial layer each comprise at least one of silicon oxide, silicon oxynitride, or silicon oxide doped with a non-metal element,
the first bowing prevention layer and the second bowing prevention layer each comprise at least one of silicon nitride or silicon nitride doped with a non-metal element, and
the bowing prevention buffer layer comprises at least one of silicon oxynitride or silicon oxynitride doped with a non-metal element.

10. The semiconductor structure of claim 1, wherein the semiconductor chips each comprise at least one capacitor, and a supporter layer between lower electrodes included in the at least one capacitor.

11. A semiconductor structure on a substrate, the semiconductor structure comprising:
a chip region comprising a plurality of semiconductor chips on the substrate; and
a peripheral region at a periphery of the chip region, the peripheral region including a mold structure,
wherein the mold structure comprises
a base mold layer on the substrate,
a composite mold layer on the base mold layer, the composite mold layer comprising at least one bowing sacrificial layer and at least one bowing prevention layer; and
a supporter layer under the base mold layer or on the composite mold layer.

12. The semiconductor structure of claim 11, wherein
the at least one bowing sacrificial layer comprises at least one of silicon oxide, silicon oxynitride, or silicon oxide doped with a non-metal element,
the at least one bowing prevention layer comprises at least one of silicon nitride or silicon nitride doped with a non-metal element, and
the supporter layer comprises silicon carbon nitride.

13. The semiconductor structure of claim 11, wherein
the composite mold layer comprises a plurality of bowing sacrificial layers and a plurality of bowing prevention layers such that the plurality of bowing sacrificial layers and the plurality of bowing prevention layers are alternately stacked, and
a bowing prevention buffer layer between a first bowing sacrificial layer of the plurality of bowing sacrificial layers and a first bowing prevention layer of the plurality of bowing prevention layers.

14. The semiconductor structure of claim 13, wherein
the plurality of bowing sacrificial layer comprises at least one of silicon oxide, silicon oxynitride, or silicon oxide doped with a non-metal element,
the plurality of bowing prevention layer comprises at least one of silicon nitride or silicon nitride doped with a non-metal element, and
the bowing prevention buffer layer comprises at least one of silicon oxynitride or silicon oxynitride doped with a non-metal element.

15. The semiconductor structure of claim 11, wherein
the semiconductor chips each comprise at least one capacitor, and
the supporter layer is between lower electrodes included in the at least one capacitor.

16. A semiconductor structure on a substrate, the semiconductor structure comprising:
a chip region comprising a plurality of semiconductor chips on the substrate; and
a peripheral region at a periphery of the chip region and comprising a mold structure,
wherein the mold structure comprises
a lower base mold layer on the substrate,
a lower supporter layer on the lower base mold layer,
an upper base mold layer on the lower supporter layer,
a composite mold layer on the upper base mold layer and comprising at least one bowing sacrificial layer and at least one bowing prevention layer, and
an upper supporter layer on the composite mold layer.

17. The semiconductor structure of claim 16, wherein
the lower base mold layer and the upper base mold layer comprise silicon oxide,
the at least one bowing sacrificial layer comprises at least one of silicon oxide or silicon oxide doped with at least one of hydrogen, carbon, boron, phosphorus, or arsenic,
the at least one bowing prevention layer comprises at least one of silicon nitride or silicon nitride doped with at least one of hydrogen, carbon, boron, phosphorus, or arsenic, and
at least one of the lower supporter layer or the upper supporter layer comprises silicon carbon nitride.

18. The semiconductor structure of claim 16, further comprising:
a bowing prevention buffer layer between the at least one bowing sacrificial layer and the at least one bowing prevention layer,
wherein the at least one bowing sacrificial layer comprises at least one of silicon oxide, silicon oxynitride, or silicon oxide doped with at least one of hydrogen, carbon, boron, phosphorus, or arsenic,
the at least one bowing prevention layer comprises at least one of silicon nitride or silicon nitride doped with at least one of hydrogen, carbon, boron, phosphorus, and arsenic, and
the bowing prevention buffer layer comprises at least one of silicon oxynitride or silicon oxynitride doped with at least one of hydrogen, carbon, boron, phosphorus, and arsenic.

19. The semiconductor structure of claim 17 further comprising:
an intermediate supporter layer on the composite mold layer and
a composite mold protection layer between the intermediate supporter layer and the upper supporter layer,
wherein the intermediate supporter layer comprises silicon carbon nitride, and
the composite mold protection layer comprises silicon nitride.

20. The semiconductor structure of claim 16, wherein
the plurality of semiconductor chips each comprise at least one capacitor, and
the lower supporter layer and the upper supporter layer are between lower electrodes included in the at least one capacitor.
